(19) United States
(12) Patent Application Publication
(10) Pub. No.: US 2010/0200781 A1
(43) Pub. Date: Aug. 12, 2010

(54) METHOD AND APPARATUS FOR MANIPULATING AND DETECTING ANALYTES

(76) Inventors: Maziyar Khorasani, Edmonton (CA); Duncan Elliott, Edmonton (CA)

Correspondence Address: BARNES & THORNBURG LLP, 11 SOUTH MERIDIAN, INDIANAPOLIS, IN, 46204, US

(21) Appl. No.: 12/702,035

(22) Filed: Feb. 8, 2010

Related U.S. Application Data
(60) Provisional application No. 61/150,460, filed on Feb. 6, 2009.

(30) Foreign Application Priority Data
Feb. 5, 2010 (WO) PCTCA2010000138

(51) Int. Cl. G01N 21/64; G01R 27/08; G01N 27/00; G01N 21/85

(52) U.S. Cl. 250/576; 324/722; 324/71.1; 250/458.1; 250/459.1

(57) ABSTRACT

A first integrated circuit operable in association with a microfluidic structure is provided that includes a field generator, a controller configured to control the field generator to generate at least one field to effect movement of at least one analyte of interest in a fluid contained in the microfluidic structure, and an optical detection component configured to optically detect the at least one analyte of interest, as movement of the at least one analyte of interest through the microfluidic structure is effected by the at least one field. A second integrated circuit operable in association with a microfluidic structure is also provided that includes an optical detector configured to generate an output indicative of light from at least one analyte of interest in a fluid within the microfluidic structure; and circuitry configured to convert the output of the optical detector to a digital value.

### CROSS REFERENCE TO RELATED APPLICATIONS

This application claims the benefit of prior U.S. Provisional Application No. 61/150,460 filed Feb. 6, 2009, and also claims the benefit of PCT Application No. PCT/CA2010/000138 filed Feb. 5, 2010, both of which are hereby incorporated by reference in their entireties.

### FIELD OF THE INVENTION

The present invention relates to biological and/or chemical analysis in general, and to integrated implementations for manipulation and detection of analytes, in particular.

### BACKGROUND OF THE INVENTION

In biological and chemical sciences, there are many applications that benefit from the ability to manipulate and detect specific objects or analytes. Current state-of-art systems incorporate various forms of electric and/or magnetic fields for manipulation, and a plurality of methods for detection, including spectroscopic (UV, fluorescence), electrochemical, and capacitively coupled contactless conductivity detection, as a few examples.

In one conventional implementation, an analyte is bound to specially coated superparamagnetic particles (a.k.a. magnetic beads) and a magnetic field is used to externally manipulate the tagged object.

In another implementation, the electrophoresis phenomenon is used to move and manipulate samples, particles or other objects suspended in an aqueous solution. The particles are manipulated under the influence of an electric field because of an electric surface charge that forms on the object when it is placed in a fluid. This method benefits from the inherent charge of the particles versus requiring analytes to be magnetically tagged.

Manipulation and movement is performed to isolate analytes of interest from unwanted samples to enable detection mechanisms to confirm its presence or absence.

Laser-induced fluorescence (LIF) is an example of a conventionally used method of detection. In LIF, the sample of interest is tagged with a fluorescently marked label (a.k.a., a fluorophore). When excited by an excitation source (e.g., laser, light-emitting-diode), the fluorophore emits photons of a different wavelength. The excitation source can be filtered, and a detector (e.g., CCD, photodiode, photomultiplier, avalanche photodiode, phototransistor) is used to detect the emitted light.

In another implementation, electrochemical detectors measure varying currents from bio-molecular reactions flowing over biologically-compatible surface electrodes.

Capacitively coupled contactless conductivity detection is another electrode based implementation. In this scheme, two electrodes are placed around a fluidic channel and an AC voltage is applied through one electrode. This results in current pick-up in the second electrode, which is then further amplified and processed.

Microfluidics deal with small volumes (e.g., nl, pl, fl) of fluids geometrically constrained to small (sub-millimeter) dimensions. By reducing the size of the fluidic channels, microfluidic-based systems can offer higher resolution and sensitivity, use smaller quantities of samples and reagents, and become more amenable to portable use and integration.

Integrated circuit or microelectronics technology allows similar miniaturization of the electronics. Leveraging continually shrinking feature sizes, complex instrumentation have been scaled to dimensions that promote integration.

### SUMMARY

According to a first aspect of the present invention, there is provided an integrated circuit operable in association with a microfluidic structure, said integrated circuit comprising: a field generator; a controller configured to control the field generator to generate at least one field to effect movement of at least one analyte of interest in a fluid contained in the microfluidic structure; and an optical detection component configured to optically detect the at least one analyte of interest, as movement of the at least one analyte of interest through the microfluidic structure is effected by the at least one field.

According to a second aspect of the present invention, there is provided an apparatus comprising: a microfluidic structure; and an integrated circuit according to the first aspect of the present invention operable in association with the microfluidic structure.

According to a third aspect of the present invention, there is provided a method in an integrated circuit operable in association with a microfluidic structure, said method comprising: generating at least one field to effect movement of at least one analyte of interest in a fluid contained in the microfluidic structure; and optically detecting the at least one analyte of interest, as movement of the at least one analyte of interest through the microfluidic structure is effected by the at least one field.

According to a fourth aspect of the present invention, there is provided an integrated circuit operable in association with a microfluidic structure,

said integrated circuit comprising: an optical detector configured to generate an output indicative of light from at least one analyte of interest in a fluid within the microfluidic structure; and circuitry configured to convert the output of the optical detector to a digital value.

According to a fifth aspect of the present invention, there is provided an apparatus comprising: a microfluidic structure; and an integrated circuit according to the fourth aspect of the present invention operable in association with the microfluidic structure.

In some aspects, the present invention involves the use of a CMOS compatible BioMEMS and/or microfluidic process wafer-level bonded with conventional semiconductor technologies (e.g., Si, SiGe, CMOS, HV CMOS, GaAs, InP, SOI) to build a device capable of manipulation and detection of an object through fabricated microchannels using circuits and detectors designed in conventional semiconductor processes, for the variety of applications that require such mechanisms. Given the plurality of combinations possible with such integration, various embodiments are introduced.

For example, one embodiment is directed towards a system combining wells and channels and other structures in the fluidics, as required for particular functionality, wafer-level bonded with manipulation and detection circuitry implemented on an IC chip, fabricated using standard BioMEMS and/or microfluidics and a standard CMOS (e.g., HV CMOS) process respectively.

The manipulation circuitry involves power electronic components such as power-converter (e.g., DC-DC boost converters or charge pump) circuits for generating a high-voltage supply for electrophoretic operations or actuation of microfluidic based switches. Additionally, level-shifter circuits interfaced to the high-voltage supply and digital logic may be used to drive high-voltage output circuits connected to additional structures such as electrodes. Low-voltage circuits may be used to implement various sense and smart circuitry.

In some embodiments, detectors are implemented in the same standard process, if supported, using a plurality of components ranging from photodiodes, avalanche and PIN photodiodes, phototransistors, and charge-coupled devices (CCDs), all coupled to amplification and processing circuits. Additional control logic and readout circuits may also be present, along with analog-to-digital converters and digital-to-analog converters. Various sensors may also be used to measure various voltages and currents present on the IC chip.

In some embodiments, the detectors may be positioned in various places below the micro channels to allow for optimal proximity based detection. A filter may or may not be present between the detector(s) and the fluidics.

In another embodiment, an array of microelectronic magnets, or “microcoils,” may be implemented on the IC chip and configured to produce a magnetic field for manipulation.

In yet another embodiment, the IC chip may be used to control a resistance heater formed using either the standard CMOS process or post-processing of an additional layer between the semiconductor surface and the fluidics.

In some embodiments, an integrated temperature sensing circuit on the IC chip may be used to track the temperature for a variety of applications (e.g., temperature control through feedback).

Additional sources of detection may also be incorporated. These include electrochemical means through biologically-compatible surface-electrodes or capacitively coupled contactless conductivity detection through electrodes surrounding the fluidics.

In connection with any of the foregoing embodiments, the fluidic channels and wells wafer-level bonded overtop of the IC may be used in the introduction and removal of specific objects, which can then be manipulated and detected by the mechanisms introduced above. The fluidics may include not only wells and channels, but also valves and other functional blocks.

In yet another embodiment, additional structures may be available through etching techniques of the semiconductor substrate to release specific structures.

In some embodiments, an integrated excitation source is included to provide excitation light to the fluidics in order to cause one or more analytes of interest in a fluid contained in the fluidics to emit fluorescence light.

An embodiment provides a method for making a device to manipulate and detect at least one sample suspended in a fluid, contained in a second means placed on top of a first means.

In some embodiments, the second means is a microfluidic system.

In some embodiments, the microfluidic system includes one or more layers.

In some embodiments, the first means includes one or more layers.

In some embodiments, at least one of the layers of the first means is a semiconductor device.

In some embodiments, at least one of the layers of the first means is a filter.

In some embodiments, the semiconductor device is fabricated using conventional semiconductor techniques, the conventional semiconductor techniques being any of: Si, SiGe, CMOS, GaAs, InP.

In some embodiments, the semiconductor device comprises a field-generating component, a detection, imaging or characterization component, or a controller.

In some embodiments, the field generating component is a component to generate at least one electric or magnetic field having a sufficient strength to interact with at least one sample suspended in the fluid.

In some embodiments, the detection, imaging or characterization component is a component with sufficient sensitivity to resolve at least one sample suspended in the fluid.

In some embodiments, the controller is a component configured to control the at least one field-generating component or detection, imaging, or characterization component.

In some embodiments, the field-generating component includes a means of generating a sufficient voltage or current, a means of switching the generated voltage or current, and a means of outputting said electric or magnetic field.

In some embodiments, at least one of the means of generating a sufficient voltage or current is a DC-DC converter, the DC-DC converter being either capacitive or inductive.

In some embodiments, at least one of the means of switching the generated voltage or current is a level-shift circuit, said level-shift circuit connected to an output driver.

In some embodiments, at least one of the means of outputting the generated voltage or current is an output, said output being either an electrode or integrated electromagnet, such as a microcoil.

In some embodiments, at least one of the means of detection, imaging, or characterization is optical, the optical means being any combination of photodiode, avalanche photodiode, PIN photodiode, phototransistor or charge-coupled device (CCD).

In some embodiments, at least one of the means of detection, imaging, or characterization is electrochemical.

In some embodiments, at least one of the means of detection, imaging, or characterization is capacitively coupled contactless conductivity detection.

In some embodiments, at least one of the means of control employs an analog-to-digital converter or digital-to-analog converter.

In some embodiments, at least one of the means of control communicates with an external processor.

In some embodiments, the microfluidic system includes at least one microfluidic channel or reservoir.

Yet another embodiment provides a microelectronic-microfluidic device comprising microfluidic channels coupled via electrodes to microelectronics.

In some embodiments, the microelectronics include a plurality of DMOSFETs.

In some embodiments, the microelectronics include optoelectronics optically coupled to the microfluidics.

In some embodiments, the microelectronics includes one or more analog-to-digital converters.

In some embodiments, the microelectronics includes a computer interface.

In some embodiments, the microelectronics includes a DC-DC converter.

In some embodiments, a single substrate includes enclosed microfluidic channels and semiconductor microelectronic circuits.

In some embodiments, the microelectronic circuits are used to: generate high voltages with, for example, DC-DC converters and high voltage switches; sense high voltages and currents; amplify and measure signals from optoelectronic devices; provide analog-to-digital and digital-to-analog converters; and provide at least one digital computer interface.

In some embodiments, the microelectronic circuits are coupled to electrodes, which are exposed to fluid in the microfluidic structures above the electronics.

In some embodiments, the close proximity of microfluidic structures (e.g. channels, wells and chambers) to diffused semiconductor regions allows optoelectronic devices to effectively capture emitted light from the fluid without requiring lenses or waveguides.

In some embodiments, a filter layer filters and reduces the intensity of the excitation light reaching the optoelectronic devices.

In some embodiments, the high voltage circuits employ double-diffused high voltage MOSFETS (DMOS), which can have breakdown voltages in excess of 300V.

In some embodiments, logic circuits or a microprocessor, or a combination thereof, control the circuitry.

In some embodiments, the microfluidic structures are designed using multiple layers of photosensitive polymer applied to a semiconductor wafer then patterned with photolithography, or patterned then transferred on to the semiconductor wafer. For the case of 3 layers, openings in the polymer layer on the wafer (the “floor”) are used for connecting to electrodes. The next layer forms the “walls” of microfluidic structures. A third layer forms the ceiling, which is patterned with openings where microfluidic well openings or couplings to other apparatus are required.

The above apparatus can be used for analyzing samples. For the case of an electrophoretic analysis, high voltage is switched to electrodes, causing charged molecules to move in microfluidic structures. Fluorescent emissions are detected by the optoelectronics below microfluidic structures. Instrumentation receives the electrical signal from the optoelectronics, amplifies it and digitally quantifies it. Through a computer interface the electrodes are switched, voltages are controlled, and light intensities, voltages and currents are read.

Various methods and systems are described that provide, in some embodiments, monolithic microfluidic capillary electrophoresis systems.

Some embodiments of the present invention include high-voltage (HV) CMOS integrated circuits to replace the large external power supplies that are often utilized in conventional analysis systems. In some embodiments, the microelectronics and optical detectors are integrated on a single HV CMOS substrate, which can potentially reduce the size and cost of existing systems.

Some embodiments of the present invention include a microfluidic structure in proximity to microelectronic circuitry that includes an integrated voltage level shifter, for example a 5V to 50V conversion using a DC-DC boost converter (with 60 μA current source capability), for manipulation of an analyte in a fluid placed in microfluidic structure, and a picowatt sensitive integrated photodiode and transimpedance amplifier (TIA) circuit for detection of an analyte and/or distinguishing between different analytes.

In some embodiments, an optical filter is provided between the microfluidics and the microelectronics in order to filter one or more wavelengths of light prior to the photodiode.

In some embodiments, the microelectronic circuitry further includes a successive approximation Analog-to-Digital Converter (ADC) that is configured to digitize outputs of the TIA.

In some embodiments, the microelectronic circuitry further includes a serial peripheral interface configured to communicate with a personal computer (PC).

The foregoing description includes many detailed and specific embodiments that are provided by way of example only, and should not be construed as limiting the scope of the present invention. Alterations, modifications and variations may be effected to the particular embodiments by those of skill in the art without departing from the scope of the invention, which is defined solely by the claims appended hereto.

Other aspects and features of the present invention will become apparent, to those ordinarily skilled in the art, upon review of the following description of the specific embodiments of the invention.

### BRIEF DESCRIPTION OF THE DRAWINGS

Embodiments of the present invention will now be described, by way of example only, with reference to the accompanying drawing figures, wherein:

FIG. 1 is a block diagram of an apparatus for the manipulation and analysis of an analyte in a fluid, in accordance with an embodiment of the present invention;

FIG. 2 illustrates an exemplary physical arrangement of an apparatus for the manipulation and analysis of an analyte in a fluid, in accordance with an embodiment of the present invention;

FIG. 3 is a diagram of the spectral response of a red pigment optical filter and a green laser excitation light overlayed with the emission and excitation spectra of a ROX fluorophore, in accordance with an embodiment of the present invention;

FIG. 4 is a perspective view of the apparatus of FIG. 2 showing a cross section of the apparatus, in accordance with an embodiment of the present invention;

FIG. 5 is a cross-sectional view of an exemplary physical arrangement of a hybrid optical filter and a photodiode that is used in an embodiment of the present invention;

FIG. 6 is a schematic of a basic inductive DC-DC boost converter circuit, in accordance with an embodiment of the present invention;

FIG. 7 is an exemplary plot of the gain dependence (for a duty cycle D) on output-input current ratio for the discontinuous and continuous modes of operation of a DC-DC boost converter circuit;

FIG. 8 is an exemplary plot of current and switching state for a boost converter operating in the continuous mode;

FIG. 9 is an exemplary plot of current and switching state for a boost converter operating in the discontinuous mode;

FIG. 10 is a block diagram of the control circuit used to control a DC-DC boost converter, in accordance with an embodiment of the present invention;

FIG. 11 is a schematic of a DC-DC boost converter and its associated control circuit and voltage divider, in accordance with an embodiment of the present invention;

FIG. 12 is a block diagram of a level-shifter and an output driver, in accordance with an embodiment of the present invention;

FIG. 13 is an exemplary schematic of a pseudo-NMOS level-shifter and output driver, in accordance with an embodiment of the present invention;

FIG. 14 is an exemplary schematic of a pseudo-NMOS with current limit level-shifter and output driver, in accordance with an embodiment of the present invention;

FIG. 15 is an exemplary schematic of a 3T resistive load level-shifter and output driver, in accordance with an embodiment of the present invention;

FIG. 16 is an exemplary schematic of a fully static level-shifter and output driver in accordance with an embodiment of the present invention;

FIG. 17 is an exemplary schematic of a dynamic level-shifter with a zener diode and output driver, in accordance with an embodiment of the present invention;

FIG. 18A is a cross-sectional view of an p+/Deep N-Well photodiode, in accordance with an embodiment of the present invention;

FIG. 18B is a cross-sectional view of a P-Well/n+ photodiode, in accordance with an embodiment of the present invention;

FIG. 18C is a cross-sectional view of an P-Epi/Deep N-Well photodiode, in accordance with an embodiment of the present invention;

FIG. 18D is a cross-sectional view of an P-Epi/HV N-Well photodiode, in accordance with an embodiment of the present invention;

FIG. 18E is a cross-sectional view of an P-Base/HV N-Well photodiode, in accordance with an embodiment of the present invention;

FIG. 19A is a cross-sectional view of a low voltage edge guard ring avalanche photodiode, in accordance with an embodiment of the present invention;

FIG. 19B is a cross-sectional view of a high voltage edge guard ring avalanche photodiode, in accordance with an embodiment of the present invention;

FIG. 19C is a cross-sectional view of a n+ virtual guard ring avalanche photodiode, in accordance with an embodiment of the present invention;

FIG. 19D is a cross-sectional view of a p+ virtual guard ring avalanche photodiode, in accordance with an embodiment of the present invention;

FIG. 20 is a schematic of an exemplary three-stage optical detection component, in accordance with an embodiment of the present invention;

FIG. 21 is a schematic of an exemplary avalanche photodiode quenched circuit in accordance with an embodiment of the present invention; and

FIG. 22 is a flowchart for a method in an integrated circuit of manipulating and detecting an analyte in a microfluidic structure.

Common reference numbers have been used to identify components having the same or similar functionality throughout the drawings.

### DETAILED DESCRIPTION

In the following detailed description of sample embodiments, reference is made to the accompanying drawings, which form a part hereof, and in which is shown by way of illustration specific sample embodiments in which the present invention may be practised. These embodiments are described in sufficient detail to enable those skilled in the art to practice the invention, and it is to be understood that other embodiments may be utilized and that logical, mechanical, electrical, and other changes may be made without departing from the scope of the invention. The following detailed description is, therefore, not to be taken in a limiting sense, and the scope is defined by the appended claims.

An apparatus and a method are provided that integrate microfluidics with microelectronics and optoelectronics for integrated manipulation and detection of an analyte.

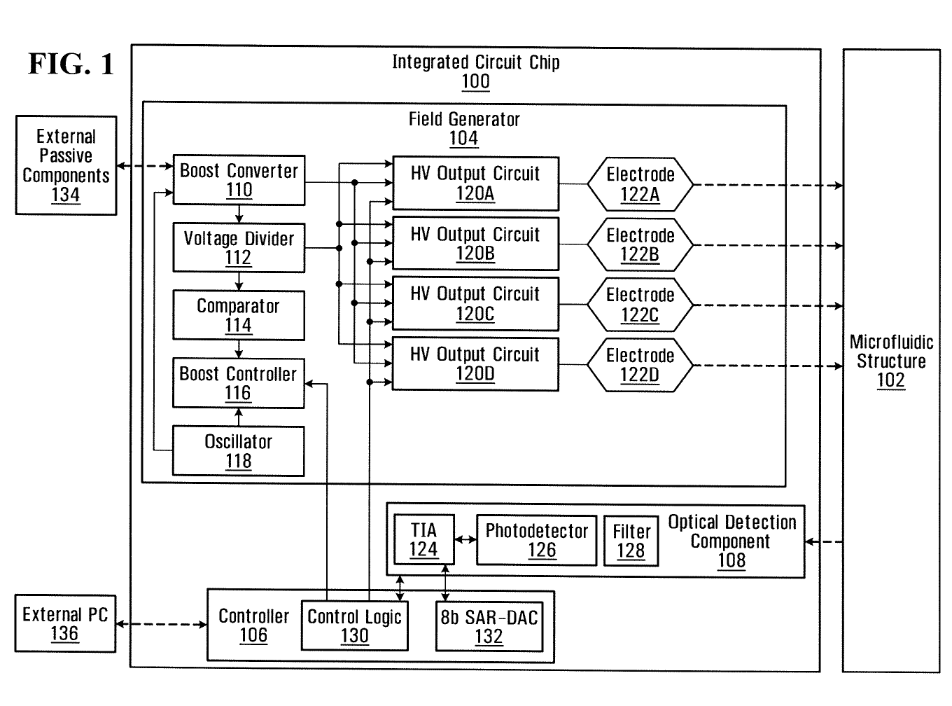

An apparatus in accordance with an embodiment of the present invention will now be described with reference to FIG. 1.

FIG. 1 is a block diagram of an apparatus for the manipulation and analysis of an analyte in a fluid, in accordance with an embodiment of the present invention. The apparatus includes an integrated circuit chip 100, and a microfluidic structure 102. In some cases, the apparatus may also include external passive components 134 and/or an external personal computer 136 functionally connected to integrated circuit chip 100.

Integrated circuit chip 100 includes a field generator 104, an optical detection component 108 and a controller 106.

Field generator 104 includes a boost converter 110, a voltage divider 112, a comparator 114, a boost controller 116, an oscillator 118, four high voltage (HV) output circuits 120A-120D and four microelectronic electrodes 122A-122D. A first output of the boost converter 110 is functionally connected to a respective first input of each of HV output circuits 120A-120D. A second output of boost converter 110 is functionally connected to an input of voltage divider 112. A first output of voltage divider 112 is functionally connected to a respective second input of each of HV output circuits 120A-120D. A second output of voltage divider 112 is functionally connected to a first input of boost controller 116. A first output of boost controller 116 is functionally connected to a first input of boost converter 110. A second input of boost controller 116 is functionally connected to an output of oscillator 118. In some cases, boost converter 110 may also be functionally connected off-chip to one or more external passive components 134.

The controller 106 includes control logic 130 and an 8-bit successive approximation register digital-to-analog converter (SAR-DAC) 132. A first output of control logic 130 is functionally connected to a third input of boost controller 116. A second output of control logic 130 functionally connected to a respective third input of each of HV output circuits 120A-120D. Each of HV output circuits 120A-120D is connected to a respective one of the four microelectronic electrodes 122A-122D.

Optical detection component 108 includes a photodetector 126 and a transimpedance amplifier (TIA) 124. In some embodiments, as shown in FIG. 1, optical detection component 108 also includes an optical filter 128 that is configured to filter light reaching photodetector 126. Photodetector 126 is functionally connected to TIA 124, which also has functional connections to control logic 130 and 8-bit SAR-DAC 132 of controller 106. In some cases the apparatus also includes a communication interface between controller 106 and external PC 136.

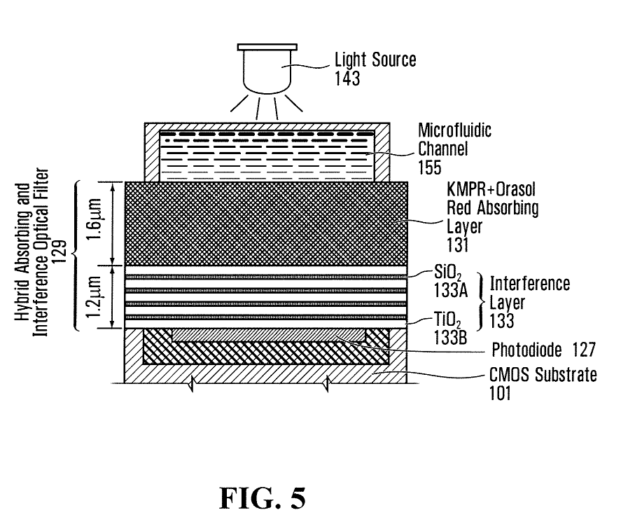

A detailed description of the individual components of field generator 104, optical detection component 108 and controller 106 is provided later with reference to exemplary embodiments of the individual components in FIG. 5 to FIG. 21. As such, only a description of the functionality of the higher level blocks, i.e., microfluidic structure 102 and field generator 104, optical detection component 108 and controller 106 of integrated circuit chip 100 will be provided with respect to FIG. 1.

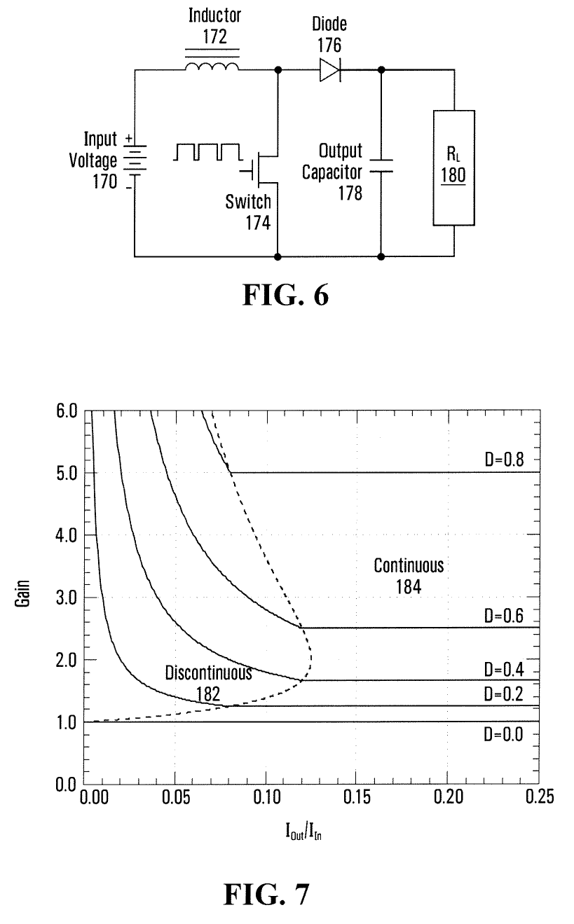

The microfluidic structure 102 is configured to contain a fluid carrying an analyte of interest in proximity to integrated circuit chip 100. Controller 106 configured to control field generator 104 to generate at least one electric and/or magnetic field to manipulate the analyte in the fluid contained in microfluidic structure 102. The components that are included in Field generator 104 in FIG. 1 are only one example of components that may be used to generate one or more fields in accordance with an embodiment of the present invention. For example, in the illustrated example, a boost converter 110, exemplary implementations of which are discussed later with respect to FIG. 6 to FIG. 11, is only one example of a component that may be used to produce a high voltage for the purposes of generating an electric field that is sufficient to interact with an analyte in microfluidic structure 102. In some embodiments, similar functionality provided by, for example, a charge pump circuit.

Microfluidic structure 102 may have one or more microfluidic wells, channels and/or reservoirs for the addition and/or transport of fluid. Controller 106 is configured to control field generator 104 to generate the at least one field such that the at least one field effects movement of the analyte of interest through a portion of microfluidic structure 102 in proximity to optical detection component 108, which is configured to optically detect the analyte of interest. Controller 106 is also configured to process output of optical detection component 108.

In some embodiments, controller 106 sends a record of output of optical detection component 108 to external PC 136.

In some embodiments, external PC 136 provides a user interface to configure operation of controller 106, and thus control operation of integrated circuit chip 100.

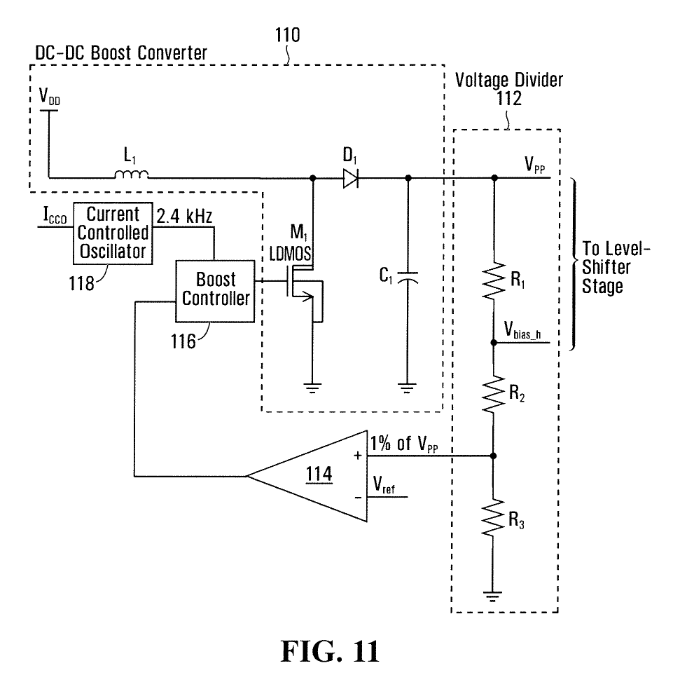

In some embodiments, the external passive components 134 include off-chip inductor(s), diode(s) and/or capacitor(s) that are used by boost converter 110 in production of voltages and/or currents sufficient to generate electric and/or magnetic field of sufficient strength to manipulate an analyte in fluid contained in microfluidic structure 102, as noted later with reference to FIG. 11.

In the exemplary embodiment shown in FIG. 1, field generator 104 is configured to generate one or more electric fields to effect movement of an analyte in microfluidic structure 102. In the illustrated embodiment, high voltages are produced by boost converter 110 in order to generate the electric field(s). More generally, field generator 104 is configured to generate one or more electric and/or magnetic field to effect movement of an analyte in microfluidic structure 102, said one or more field being generated with high voltages, low voltages or a combination of the two. For example, in some embodiments, one or more magnetic fields may be generated by driving one or more wires in integrated circuit chip 100 with low voltage signals switched by one or more transistors in order to trap or move magnetic beads associated with an analyte in microfluidic structure 102. In some embodiments, the wires may have a back-and-forth pattern or a spiral “coil”.

One potential application of an embodiment of the present invention is microfluidic electrophoresis.

Electrophoresis is a popular analysis method for medical diagnostics. It relies on the use of electric fields of hundreds of V/cm to separate and detect bio-molecules such as DNA and protein. Under an electric field, negatively charged DNA molecules move with a length-dependent mobility in a gel-filled channel, passing a fixed detector near the end of the channel. There has been significant interest in miniaturizing microfluidic electrophoresis systems from, for example, 40 cm to 8 cm channel lengths, to reduce cost and analysis times.

Another application of the aforementioned microfluidic structures, optical components and instrumentation is to perform DNA amplification. One technique to perform DNA amplification is polymerase chain reaction (PCR), which involves thermally cycling a sample DNA template in the presence of a mixture that includes a buffer, TAC enzyme, DNA primers and DNA bases. Quantitative PCR (or real time PCR) add detection capability by adding an excitation light source, a photodetector to detect fluorescence and an intercalator fluorophore that fluoresces more brightly when bound to double-stranded DNA such as the DNA replicated by the PCR.

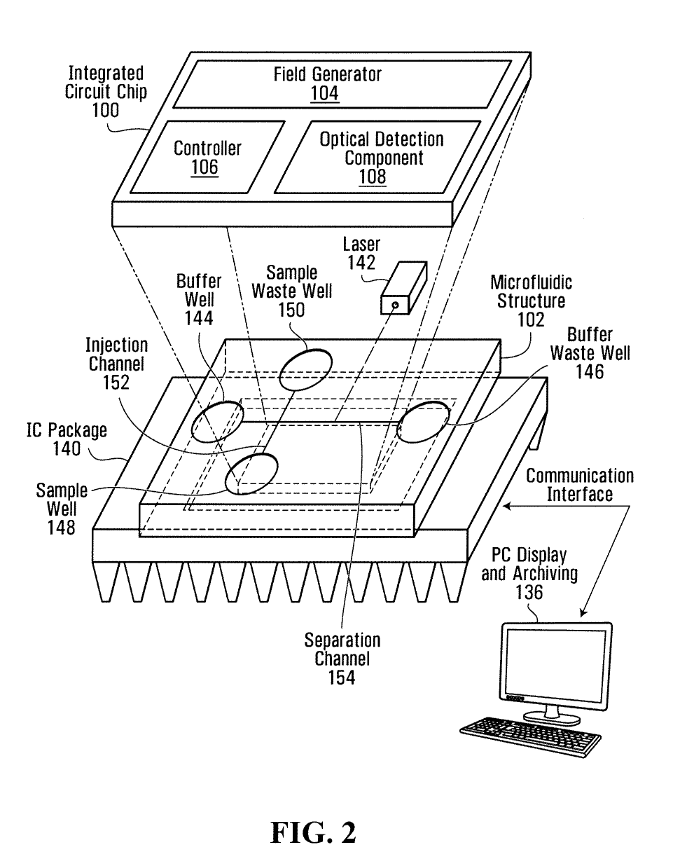

FIG. 2 illustrates an exemplary physical arrangement of an apparatus for the manipulation and analysis of an analyte in a fluid using the concepts of microfluidic electrophoresis and laser induced fluorescence (LIF), in accordance with an embodiment of the present invention.

The apparatus shown in FIG. 2 includes integrated circuit chip 100, which is mounted in an integrated circuit (IC) package 140. The apparatus also includes microfluidic structure 102, which is mounted on IC package 140 in proximity to IC chip 100, a laser 142 and an external PC 136 with a communication interface to IC package 140.

In accordance with IC chip 100 shown in FIG. 1, IC chip 100 shown in FIG. 2 includes field generator 104, controller 106 and optical detection component 108.

In FIG. 2, microfluidic structure 102 includes four microfluidic wells: sample well 148, sample waste well 150, buffer well 144 and buffer waste well 146, two intersecting microfluidic channels: injection channel 152 extending between sample well 148 and sample waste well 150 and separation channel 154 extending between buffer well 144 and buffer waste well 146. Components of field generator 104, such as the microelectronic electrodes 122A-122C shown in FIG. 1, are located such that IC chip 100 is able to apply voltages between respective pairs of wells 148-150 and 144-146, as discussed below.

Injection channel 152 is shorter than separation channel 154 and serves to electrophoretically “load” a sample when IC chip 100 applies a negative and positive potential to sample well 148 and sample waste well 150 respectively. That is, the voltage potential between the two wells created by field generator 104 of IC chip 100 draws a sample through the injection channel between the sample wells 148 and 150. Once a portion of the sample has migrated along injection channel 152, by applying a negative and positive potential to buffer well 144 and buffer waste well 146 respectively (typically while floating the potential of the sample wells 148 and 152), a “plug” of charged particles located in the precisely defined channel volume at the point of intersection of injection channel 152 and separation channel 154 is electrophoretically migrated along separation channel 154 toward buffer waste well 146. The sample drawn along separation channel 154 will separate out along separation channel 154 based on the relative size of the components of the sample. For example, if the sample includes DNA, the sample will separate out based on the size of the DNA.

Movement of a sample along separation channel 152 is typically governed by:

x=υt (1)

u=μE (2)

where x is the distance traveled, υ is the average velocity, and t is the time. Generally, the optical detection component 108 is placed as far away from the intersection of injection channel 152 and separation channel 154, thereby maximizing the distance and hence the separation time. However, as can be seen from Equations 1 and 2, where μ is the electrophoretic mobility and E is the electric field, the separation time can be decreased by increasing the electric field.

Capillary electrophoresis in conventional electrophoresis separations are normally performed using voltages, and corresponding currents, in the range of 5-30 kV and 10-100 μA respectively for channel dimensions of 20-100 cm long and 10-100 μm wide. Higher currents may lead to unstable and irreproducible operating conditions through:

1. Joule heating which can cause changes to the polymer pore sizes resulting in a non-linear separation characteristic.

2. Reduced resolution through heating and convection flow.

Because microfluidic based systems have smaller channel dimensions than capillary based systems, lower voltages can be used while maintaining the same electric fields. In regards to the voltage, if the potential is too high, some sample analytes, such as DNA, can become completely uncoiled, and regardless of size, orient themselves parallel to the field and migrates at the same velocity (a.k.a strongly biased reptation), making mobility based separation infeasible.

Typically, voltage selection takes into consideration the following issues:
Resolution and migration velocity are a function of the electric field and the polymers retarding capability. For example, lower electric fields may provide higher resolution but at the cost of much slower speeds (and vice versa). A polymer with smaller entanglements may result in enhanced resolution during separation but slower speeds (and vice versa).
Fragments of the same sample with varying lengths will experience different rates of travel (i.e. delta velocity). Thus, generally the electric field is operated at a value that allows for maximum resolution.
Depending on the conditions, currents should be maintained at a level to prevent Joule heating.

Laser induced fluorescence is an analysis technique whereby an analyte of interest, which naturally fluoresces or which can be chemically modified, i.e. “tagged”, with a fluorophore that will fluoresce when stimulated by an excitation light, is detected using an optical detector sensitive to the fluorescence. LIF is a popular detection method for biochemical analysis in microfluidic systems. This is because of its high sensitivity for low analyte concentrations, it is chemically decoupled from the analysis step, and many of the current biochemistry protocols already incorporate fluorescent labels. However, despite its advantages, LIF integration in microfluidic devices has lagged behind non-optical detection techniques such as electrochemical detection (ECD) because of its conventional dependence on large external requirements (e.g. photomultiplier tube, lens, dichroic mirror and filters).

In the embodiment shown in FIG. 2, an optical detector (not shown in FIG. 2), such as photodetector 126 shown as part of optical detection component 108 in FIG. 1, is located on IC chip 100 so that it is near the end of separation channel 154 before buffer waste well 146. Laser 142 generates laser light that is directed to intersect with separation channel 154 proximate the optical detector of IC chip 100. The optical detector is used to measure the intensity of light emitted by the excited fluorophores contained in the sample in separation channel 154 as a result of the excitation light generated by laser 142.

The excitation light generated by laser 142 has a particular wavelength. The fluorescence light emitted by the sample as a result of the excitation light has a different, and typically longer, wavelength than the excitation light. Accordingly, the excitation light from laser 142 and fluorescence light emitted by the sample in separation channel 154 can be distinguished based on wavelength.

In the exemplary embodiment illustrated in FIG. 2, an external light source, i.e. laser 142, is used to provide excitation light. In some embodiments, an excitation light source, such as a laser or LED is functionally connected to integrated circuit chip 100, and may be controlled and/or powered by integrated circuit chip 100.

In some embodiments, an optical filter, such as optical filter 128 shown as part of optical detection component 108 in FIG. 1 is used to substantially filter out excitation light wavelength(s) while substantially transmitting fluorescence light wavelength(s).

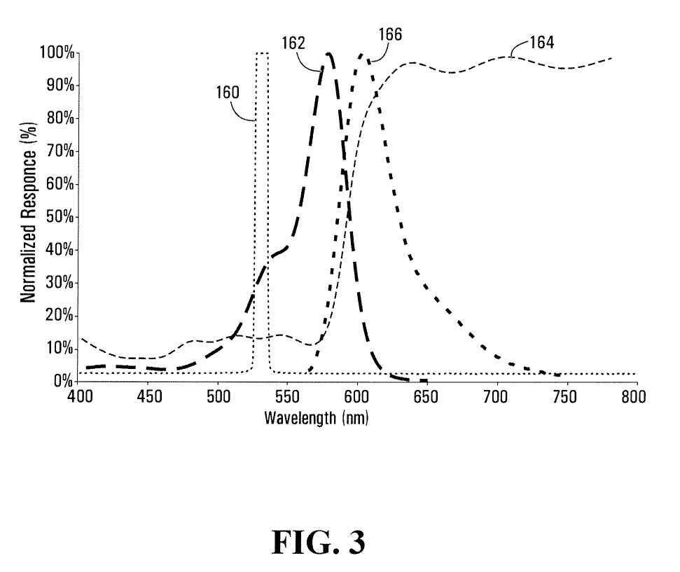

FIG. 3 is a diagram of the spectral response of a red pigment optical filter and a green (532 nm) laser excitation light overlayed with the emission and excitation spectra of a ROX (5-carboxy-X-rhodamine) fluorophore. The spectra 160 of the green laser excitation light has a peak at a wavelength of approx. 532 nm, while the spectral response 162 of the ROX fluorophore peaks above 550 nm when excited by the green laser light. The red pigment optical filter has a spectral response 164 that includes a pass band that begins above 550 nm, and therefore the resulting filtered spectral response 166 includes the portion of the ROX fluorophore spectral response 162 that falls within the passband of the filter, while substantially omitting all of the green laser excitation light that is outside the passband of the filter. The spectral response illustrated in FIG. 3 is provided as an illustrative example only, and should not be considered to be limiting as to the wavelengths, fluorophores and filter types that may be utilized in some embodiments of the present invention.

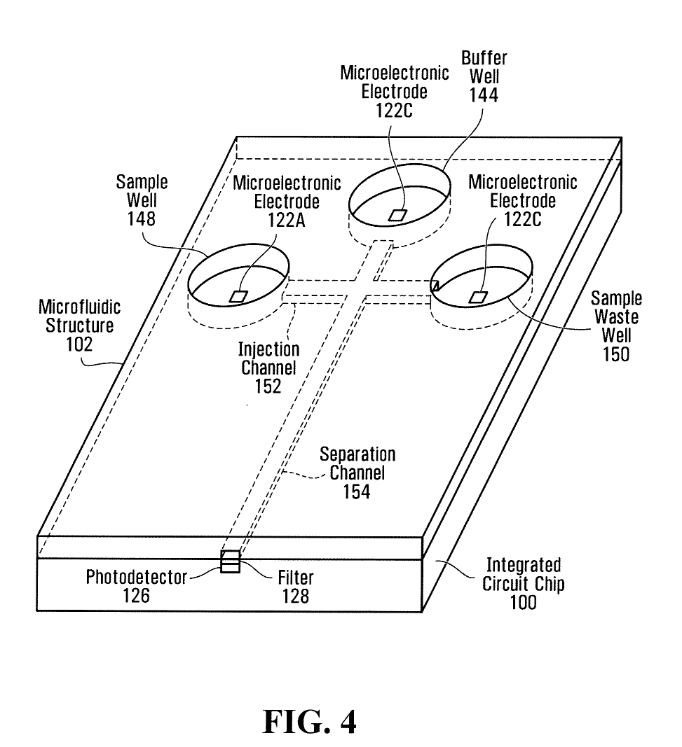

FIG. 4 is a perspective view of the apparatus of FIG. 2 showing a cross section of the apparatus at a point along separation channel 154 at which a photodetector 126 of optical detection component 108 is located for optical detection of at least one analyte moving through separation channel 154. FIG. 4 also shows microelectronic electrodes 122A, 122B and 122C located in sample well 148, sample waste well 150 and buffer well 144 respectively, which were not shown in FIG. 2. In some embodiments, microelectronic electrodes 122A, 122B, 122C and 122D (not shown in FIG. 4) are top-metal layer electrodes covered with a bio-compatible film. Examples of bio-compatible films include, but are not limited to, palladium, gold, platinum or nickel. An opening in the “floor” of microfluidic structure 102 in each well provides exposure of the respective electrode to a fluid that may be present in the well.

While electrodes 122A-122C are shown as being located in wells 144, 148 and 150 in FIG. 4, more generally output circuitry, such as electrodes, for generating electric and/or magnetic fields, may be located anywhere in relation to microfluidic components, such as channels, reservoirs and wells, of a microfluidic structure, in order to effect movement of an analyte through the microfluidic structure For example, in some embodiments, electrodes may be located in a channel, rather than in a well.

While FIG. 4 shows a single electrode 122A, 122B, 122C in each of the wells 148, 150, 144, more generally, any number of electrodes or any other type of output structure for generating an electric or magnetic field may be included in other embodiments of the present invention.

In FIG. 4, optical filter 128, which is located between separation channel 154 of microfluidic structure 102 and photodetector 126 is selected so that when excitation light from laser 142 is applied to a sample in separation channel 154 proximate photodetector 126, filter 128 substantially transmits fluorescence light emitted from the sample in response to the laser excitation light, while reducing intensity of excitation light from laser 142 reaching photodetector 126.

There are many forms of optical filters that may be utilized in various embodiments of the present invention. Non-limiting examples include interference filters, absorption filters and hybrids of the two.

Good optical filtering results can potentially be obtained with on-chip thin-film interference filters, some using 40 layers or more, as well as off-chip filters. However, the spectral performance of interference filters degrades markedly for light incident at oblique angles to the optical axis of the filter. In miniaturized highly integrated lab-on-a-chip devices, the optical components can be in very close proximity to each other so that light incident at oblique angles is actually a significant proportion of the total fluorescence incident onto the detector. Therefore, interference filters can be poor performers in such cases.

Absorption filters have also been used in integrated lab-on-a chip devices. Though their spectral performance is generally equally good at oblique angles of incidence, they tend to be limited by autofluorescence. In addition, absorption filters have much softer roll-offs compared to interference filters.

Finally, although an absorption filter will yield a high attenuation in the stopband given a thick enough film, unwanted attenuation in the passband will also increase with film thickness.

Hybrid absorbing/interference filters seek to use the advantages of each technology to offset the disadvantages of the other. The interference component minimizes the thickness required of the absorbing component and sharpens its roll-off characteristics, while the absorbing component renders the performance of the overall filter independent of the incidence angle.

One illustrative example of a hybrid interference/absorption optical filter that may be utilized in some embodiments of the present invention is shown in FIG. 5.

FIG. 5 is a cross-sectional view of an exemplary physical arrangement of a hybrid optical filter 129 and a photodiode 127 that may be used in some embodiments of the present invention.

Hybrid absorbing/interference optical filter 129 is located between photodiode 127, which is located in a CMOS substrate 101, and a microfluidic channel 155.

Hybrid absorbing/interference optical filter 129 includes a red absorbing layer stacked on top of an interference layer 133. Interference layer 133 is made up of alternating thin layers of dissimilar dielectric SiO₂ 133A and TiO₂ 133B.

In operation, excitation light from a light source 143 is incident on microfluidic channel 155. Some portion of the excitation light from light source 143 may stimulate emission of fluorescence light from a sample in microfluidic channel 155, while some other portion of the excitation light is scattered and transmitted into hybrid filter 129, which is configured to reduce the intensity of the excitation light reaching photodiode 127, while substantially transmitting fluorescence light.

With reference again to boost converter 110 shown in FIG. 1, FIG. 6 is a schematic of a basic inductive DC-DC boost converter circuit that might be used in some embodiments of the present invention.

The DC-DC boost converter circuit illustrated in FIG. 6 includes an input voltage 170, an inductor 172, a switch 174, a diode 176, an output capacitor 178 and a load 180.

This circuit steps-up input voltage 170 to higher voltage at the output across the load 180. As power must be conserved (Ohms law), the output current is lowered from the source current. In this work, the switch 174 is implemented with LDMOS (laterally diffused high-voltage NMOS) transistor(s).

With the transistor switch 174 sinking current, a magnetic field forms in the inductor 172 as current passes through it. With the transistor switch 174 off, as the magnetic field cannot collapse (and the current cannot change) instantaneously, the inductor 172 develops a large counter electromagnetic field (EMF) that forward biases the diode 176 which allows current to passes through it to charge the output capacitor 178. To reach a target voltage, the transistor switch 174 is switched repeatedly until sufficient charge is stored on capacitor 178.

Depending on the size of the load 180, the maximum output voltage (and thus gain) becomes dependent on several factors. A large load limits the gain as it places the boost converter in the continuous regime. In this mode, the gain is dependent only on the duty cycle of the switch 174. However, when the load is sufficiently small (i.e. IO/II<0.1), the boost converter operates in the discontinuous mode and the gain is dependent on the duty cycle (D), input voltage 170, and the output current (IO) and the gain can generally be higher.

In some embodiments, the transistor switch 174 is implemented with pull-down transistors.

FIG. 7 illustrates the relationship between gain and the ratio of the output to input current. The two different modes of operation are discussed in more detail below.

When the load is small, the boost converter operates in continuous mode and the current (IL) through inductor 172 never falls to zero.

Assuming all of the components are ideal, when the switch 174 is on, the inductor voltage equals the input voltage 170 and a change in current occurs given by:

$${Δ I}_{{L}_{ON}} = {\int }_{0}^{DT} \frac{{V}_{{L}_{ON}}}{L} d t = \frac{{V}_{i} DT}{L} \qquad ( 3 )$$

Where D is the duty cycle (i.e. on-time), L is the inductance of inductor 172 and T is the switching period. Assuming there is no voltage drop across the diode 176, when the switch 174 turns off, the change in current equals:

$${Δ I}_{{L}_{OFF}} = {\int }_{0}^{( 1 - D ) T} \frac{{V}_{i} - {V}_{o}}{L} d t = \frac{( {V}_{i} - {V}_{o} ) ( 1 - D ) T}{L} \qquad ( 4 )$$

As energy must be conserved, the change in inductor current during the on cycle must equal that of the off cycle. This yields:

$$\frac{{V}_{o}}{{V}_{i}} = \frac{1}{1 - D} \qquad ( 5 )$$

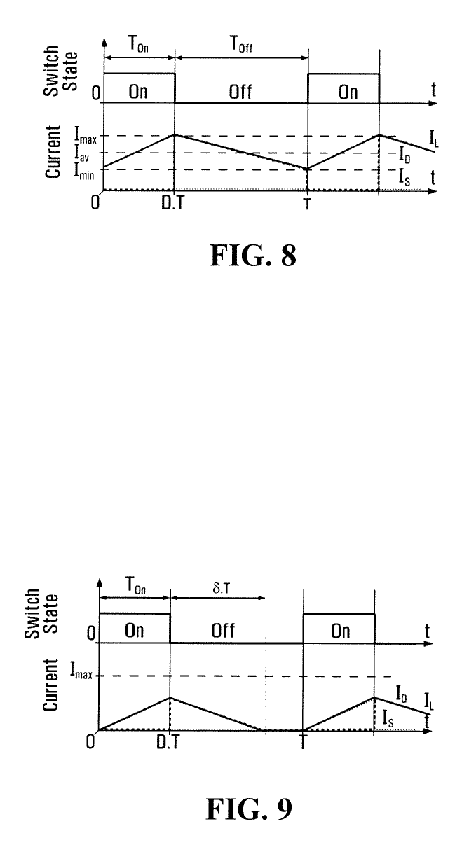

FIG. 8 is an exemplary plot of current and switching state for a boost converter operating in the continuous mode.

During the discontinuous mode of operation, the amount of energy required by the load is small enough that it can be transferred in less then a full duration of the off cycle (i.e. δT=off-time during which diode is conducting current). This results in a period of zero inductor current. When the switch 174 is on, the inductor current is initially zero but reaches a maximum defined by:

$${I}_{{L}_{MAX}} = \frac{{V}_{i} DT}{L} \qquad ( 6 )$$

When the switch is off, as the load requires less energy, the inductor current falls to zero earlier at δT. Furthermore, as the output current (Iₒ) equals the average inductor current during the off state, the output current can be written as:

$${I}_{o} = \frac{{I}_{{L}_{MAX}}}{2} δ \qquad ( 7 )$$

Knowing again that change in current during the on-time and during the off-time must be equivalent, and solving for:

$$\begin{matrix}{Δ I}_{{L}_{MAX}} + \frac{( {V}_{i} - {V}_{o} ) ( 1 - D ) T}{L} = 0 & ( 8 ) \\ Yields \text{:} & \\ δ = \frac{{V}_{i} D}{{V}_{o} - {V}_{i}} & ( 9 )\end{matrix}$$

Using (9) in (7) yields the output voltage gain in discontinuous mode:

$$\frac{{V}_{o}}{{V}_{i}} = 1 + \frac{{V}_{i} {D}^{2} T}{2 {LI}_{o}} \qquad ( 10 )$$

FIG. 9 is an exemplary plot of current and switching state for a boost converter operating in the discontinuous mode.

Because the gain can become quite large in discontinuous mode, a control circuit may be used to monitor the output voltage and ensure it remains within some threshold.

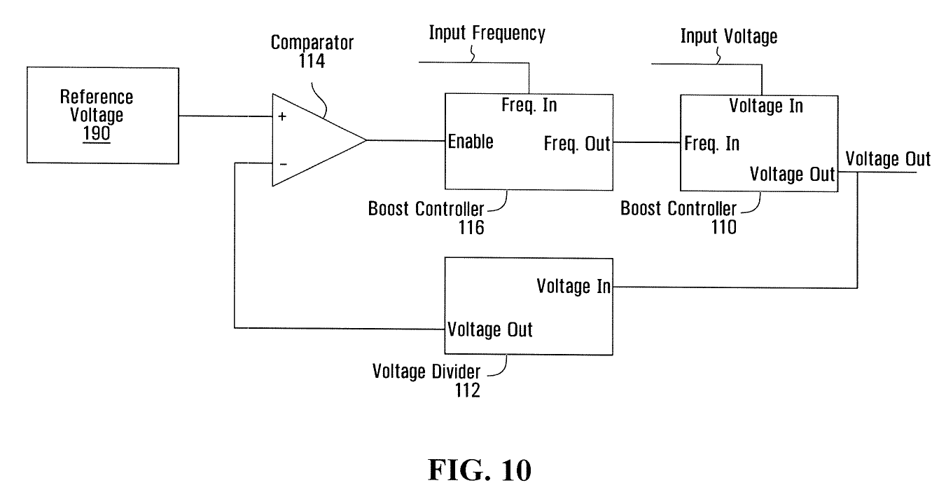

A basic control scheme for control of the DC-DC boost converter in the discontinuous mode is illustrated in FIG. 10. The control scheme illustrated in FIG. 10 includes a reference voltage 190, a comparator 114, a boost controller 116, a boost converter 110 and a voltage divider 112. In this figure, a scaled output voltage (e.g. 1%, provided by voltage divider 112) is compared with reference voltage 190 by comparator 114. If the scaled output voltage is larger than the reference voltage, the off-state of switch 174 is extended, ensuring the output voltage drops.

FIG. 11 is a schematic of an exemplary arrangement of DC-DC boost converter 110, its associated control circuitry (comparator 114, boost controller 116 and oscillator 118) and voltage divider 112, in accordance with an embodiment of the present invention. In the exemplary arrangement shown in FIG. 11, DC-DC boost converter 110 includes an inductor L₁, a diode D₁, an output capacitor C₁ and an LDMOS transistor M₁. The LDMOS transistor M₁ implements the functionality of the transistor switch 174 shown in FIG. 6.

In some embodiments, some or all of the capacitor C₁, diode D₁ and output capacitor C₁ may be implemented off-chip with external passive components.

In FIG. 11, voltage divider 112 acts as a load at the output of DC-DC boost converter 110, similar to the load 180 shown in FIG. 6. Voltage divider 112 is implemented as three serially connected resistors R₁, R₂ and R₃. Voltage divider 112 has three outputs. The first output Vₚₚ is the voltage at the output of DC-DC boost controller 110 developed across R₁, R₂ and R₃. The second output V_{bias}_{_{—}}ₕ is the voltage developed across R₂ and R₃. The third output is the voltage developed across R₃. The third output of voltage divider 112 is connected to one input of comparator 114, and, in the illustrated example, the relative sizes of R₁, R₂ and R₃ have been chosen so that the third output is equal to 1% of the first output Vₚₚ. The first and second outputs of voltage divider 112, Vₚₚ and V_{bias}_{_{—}}ₕ respectively, are provided to a level-shifter stage that, might, for example, be used to implement HV output circuits 120A-120D shown in FIG. 1.

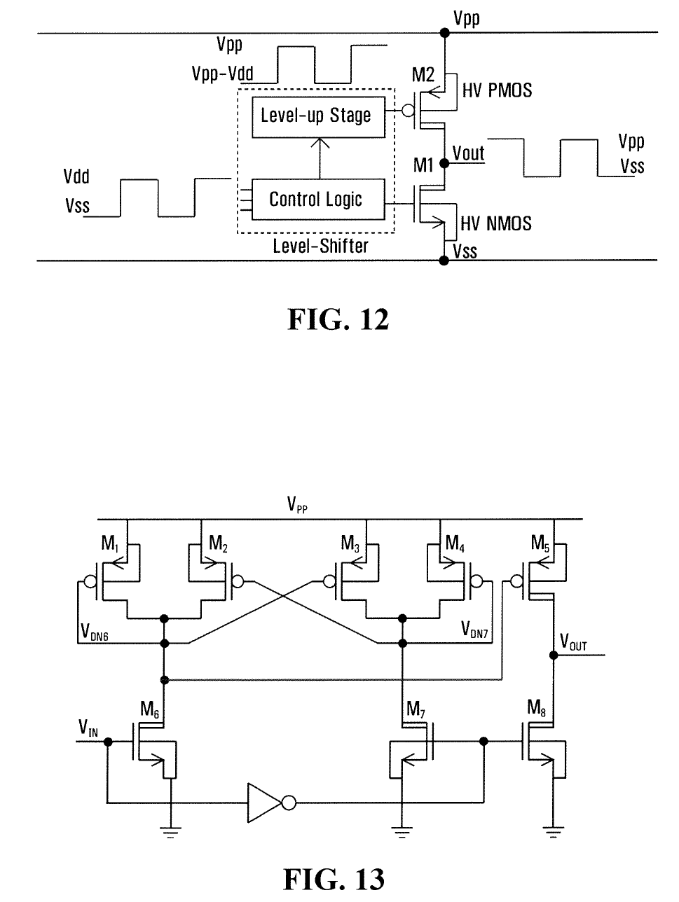

Several examples of HV output circuits that may be included in some embodiments of the present invention will now be discussed with reference to FIGS. 12-17.

FIG. 12 is a block diagram of a level-shifter and an output driver, in accordance with an embodiment of the present invention. The level-shifter includes control logic and a level-up stage, while the output driver consists of a complementary output stage that includes an Extended Drain PMOS (EDPMOS) transistor HV PMOS and a Laterally Diffused NMOS (LDMOS) transistor HV NMOS.

While the HV NMOS transistor of the output driver can be controlled by standard low-voltage, for example 5V, logic, an appropriate higher voltage signal (V_{G}<Vₚₚ−V_{THP}, where V_{G} is the gate voltage of HV PMOS, Vₚₚ is the full HV output voltage of, for example DC-DC boost converter 110, and V_{THP} is the threshold voltage of the HV PMOS transistor) is applied to the gate of the HV PMOS transistor for proper operation.

Gate voltages for the HV PMOS and HV NMOS transistors to control the outputs of the transistors is given in Table 1.

TABLE 1

| | HV NMOS | | HV PMOS | |
|---|---|---|---|---|
| Output Stage | VGHVNMOS | State | VGHVPMOS | State |
| High | <VSS + VTHN | Off | <VPP − VTHP | On |
| Float | <VSS + VTHN | Off | <VPP − VTHP | Off |
| Low | >VSS + VTHN | On | >VPP − VTHP | Off |

Five potential implementations of a level-shifting circuit with an output driver will now be described with reference to FIGS. 13-17.

FIG. 13 is an exemplary schematic of a pseudo-NMOS level-shifter and output driver that may be used in some embodiments of the present invention. The circuit illustrated in FIG. 13 includes a conventional cross-coupled level-shifter configuration. Transistors M₂ and M₃ are used as pull-ups to drive V_{DN6} and V_{DN7} to Vₚₚ, and to ensure the output EDPMOS transistor M₅ is turned completely off or on. To prevent V_{BOX} (gate oxide breakdown voltage) when either M₆ (V_{IN} high) or M₇ (V_{IN} low) are on, and when the HV supply exceeds an implementation specific maximum tolerated voltage, for example 30V, M₁ and M₄ are used to limit the voltage drop across V_{DN6} or V_{DN7} to Vₚₚ-V_{DD}.

One potential drawback of this design is the continuous power dissipation in both output high and output low conditions due to the fully-on pseudo-NMOS (LDMOS pulldown M₆ and M₇ and PMOS2 pullup M₁-M₄) configuration.

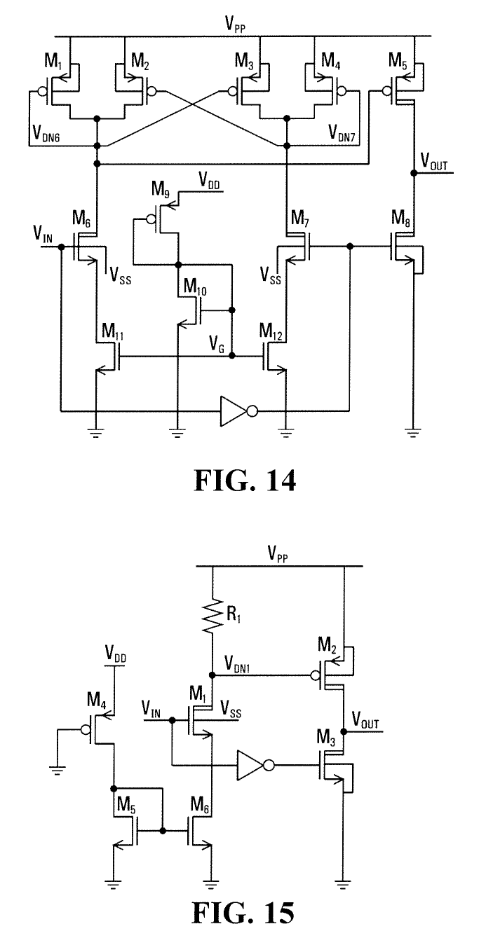

In some embodiments, to potentially reduce the power consumption associated with the implementation shown in FIG. 13, a current limiter may be included. FIG. 14 is an exemplary schematic of a pseudo-NMOS with current limit level-shifter and output driver, in accordance with an embodiment of the present invention.

In FIG. 14, a current limit is enforced by adding low voltage (LV) current mirror transistors M₁₀ and M₁₂, and a load transistor M₉. In addition, transistors M₆ and M₇ have been implemented with floating LDMOS transistors, in contrast to the transistors M₆ and M₇ in FIG. 13, which are implemented with LDMOS transistors having their bulks and sources commonly tied to ground voltage. While power consumption is reduced with these modifications, the propagation delay of the circuit increases from the reduced current, and circuit area typically increases due to the larger floating LDMOS transistors of M₆ and M₇.

FIG. 15 is an exemplary schematic of a 3T resistive load level-shifter and output driver, in accordance with an embodiment of the present invention, which can also potentially reduce power consumption. By accounting for subthreshold leakage through M₁ and appropriately sizing the resistive load R₁, the V_{GS} of the output EDPMOS transistor M₂ can be minimized to ensure it remains off. By using the current limit concept introduced in FIG. 14 in conjunction with a resistive load, not only can a sufficient voltage drop be achieved at the gate of the EDPMOS transistor M₂ during output high, but the on-current can also be controlled and reduced. For output low, as M₁ is completely off, the power dissipation is typically small as it is a function only of the subthreshold leakage.

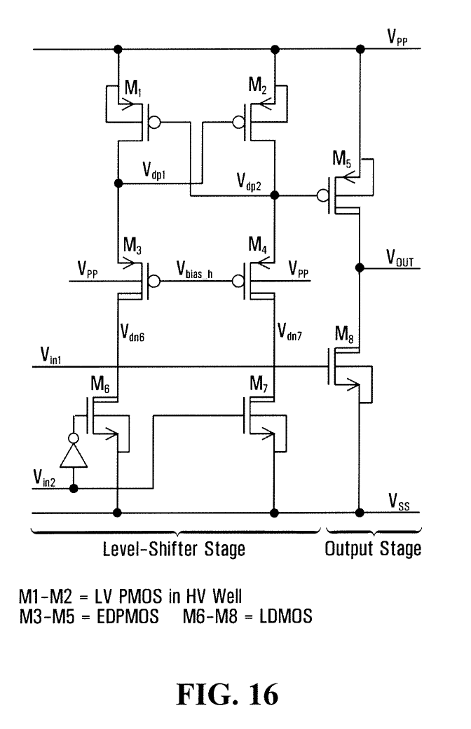

FIG. 16 is an exemplary schematic of a fully static level-shifter and output driver in accordance with an embodiment of the present invention.

While the circuit illustrated in FIG. 13 utilizes active loads to limit the voltage drop across the cross-coupled PMOS2 transistors, this design uses transistors M₃ and M₄ biased at V_{bias}_{_{—}}ₕ>V_{PP}−V_{BOX} to limit the voltage-drop and ensure the voltage at the gates of M₁, M₂ and M₅ do not exceed V. Specifically, when the input is either logic high or low, respectively, V_{dp1} or V_{dp2} are pulled low until their voltage drops below V_{bias}_{_{—}}ₕ+V_{TH}, at which point M₃ or M₄ turn off, preventing a further drop.

In the illustrated embodiment, M₁ and M₂ are implemented with medium voltage PMOS2 transistors. Gate-oxide breakdown of M₁ and M₂ due to subthreshold leakage in M₃ and M₄, respectively, is prevented by sub-nanoamp drain-bulk junction (non-permanent) breakdown of M₁ and M₂ (since V_{BDB}<V_{BOX} for the PMOS2 transistors).

As the subthreshold leakage, equivalent to the sub-nanoamp drain-bulk current, is the only continuous current draw, the power consumption of this circuit is typically reduced compared to the earlier designs. The requirement of a circuit to generate the bias voltage V_{bias}_{_{—}}ₕ is typically the main overhead of this design. In some embodiments, a voltage divider is used to generate the bias voltage at the expense of increased area and power consumption.

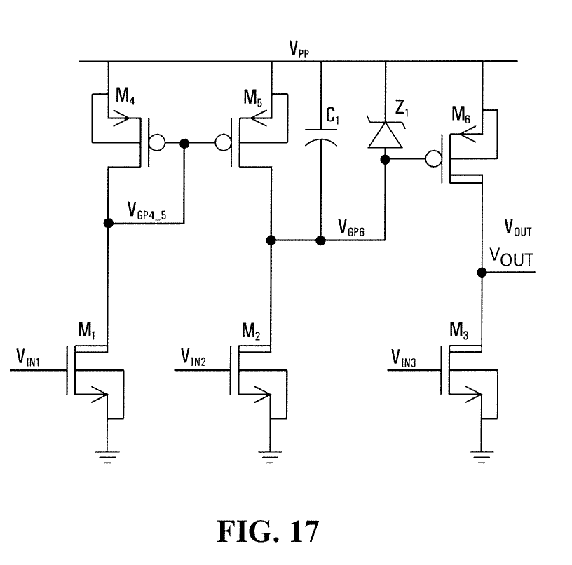

FIG. 17 is an exemplary schematic of a dynamic level-shifter and output driver, in accordance with an embodiment of the present invention. In this circuit, the charge on the gate of the output EDPMOS transistor M₆ is controlled through a dynamic scheme and power consumption may be reduced by pulsing the pulldown LDMOS transistors only for a minimum amount of time.

A strobe signal, V_{IN1} controls the operation of the level-shifter circuit. When M₂ is off and the strobe signal is high, C₁ is discharged and the output EDPMOS is turned off. However, if M₂ and the strobe are high at the same time, M₂ carries a drain current that causes a 5V drop across the PMOS2 load transistor M₅. When the strobe (and V_{IN2}) signal go low, V_{GP6} is isolated and the voltage drop is ideally retained. However, because of subthreshold (and other sources of) leakage through M₅, to maintain the level-shift operation, V_{GP6} may need to be periodically refreshed. Because power is consumed only during the strobe pulses, low average power dissipation is achieved by ensuring the duration of the strobe pulse is small. Also, since a clock signal is required for the dynamic control of input signals, crowbar current at the output stage can potentially be avoided by ensuring M₃ is off before the EDPMOS transistor M₆ turns on for output high, and turning the EDPMOS transistor M₆ on only after the output stage LDMOS transistor M₃ has been turned off for output low. Though not demonstrated here, crowbar current can also be eliminated in the static circuits.

In some embodiments, to potentially reduce power dissipation further, a Zener diode, Z₁, having a breakdown voltage of less than, for example, 15V (to prevent V_{BDS} (source to drain breakdown voltage) of the PMOS2 transistor M₅) is included as shown in FIG. 17. In these embodiments, M₂ now only needs to be pulsed for output high (rather than also pulsing the strobe signal), thus eliminating the additional current draw through M₁.

The foregoing examples of level-shifter and output stage circuits described with reference to FIGS. 12-17 have been provided for illustrative purposes only. It is to be understood that embodiments of the present invention are in no way limited to these particular examples.

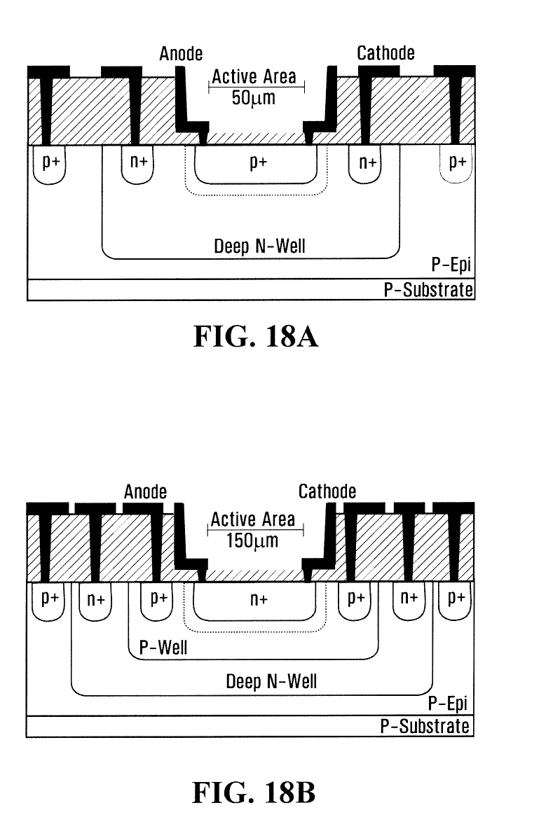

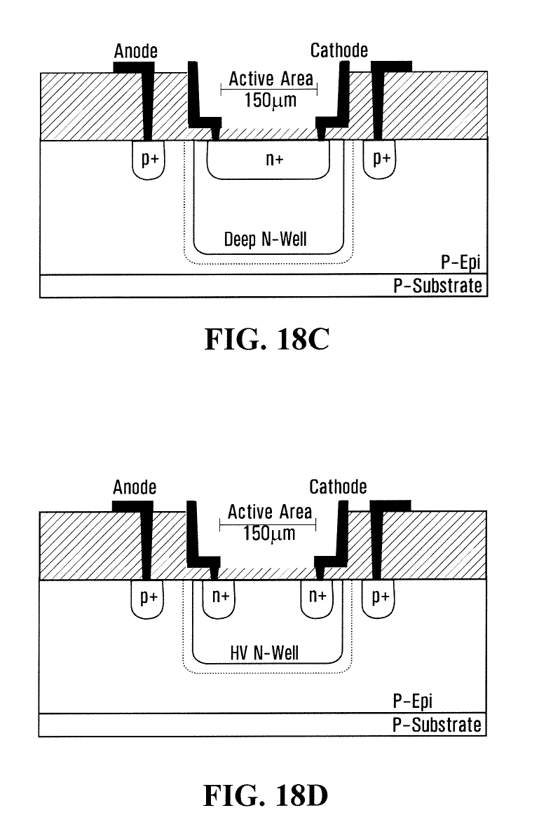

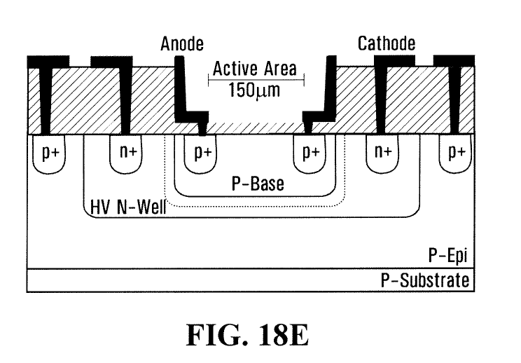

Examples of features of optical detection component 108 shown in FIG. 1 that may be included in some embodiments of the present invention will now be described with reference to FIGS. 18 to 22.

With reference first to FIGS. 1 and 4, it is noted that in some embodiments the optical detection component 108 includes a photodetector 126 configured to detect a light emission from an analyte of interest in a fluid contained in microfluidic structure 102.

To design sensors and circuits capable of sensitive optical detection of, for example, emitted florescence, as in the system illustrated in FIG. 4, first order calculations can be made to determine the optical power reaching the photodetector. For example, for induced fluorescence applications, this can potentially be done by first determining the optical power of the excitation light from the excitation light source that is absorbed by the analyte of interest, e.g. a fluorophore, and the resulting optical power it emits. Once the emission power is known, the collection efficiency of the photodetector (e.g. based on distance and its dimension, as well as the dimensions of the microfluidic structure and/or any intervening element such as an optical filter) may be used to determine the amount of optical power that reaches and is collected by the photodetector.

In this first order approximation, a black box is assumed where excitation light (e.g. from a laser), I₀, enters and emitted light (e.g. from the fluorophore), I, exits after passing through a distance, 1. This relationship can be expressed using the absorption Lambert-Bouguer law as:

I=Iₒe^{-μ}^{ₐ}^{l} (11)

where μₐ, the absorption coefficient, is a property of a material that defines the extent to which the material absorbs energy.

According to Beer-Lambert absorption, the absorption coefficient of a compound is linearly related to its concentration, c, given by:

μₐ=αc (12)

where α is called the specific absorption coefficient. Based on this principle, the Beer-Lambert law is then determined by substituting μₐ into the Lambert-Bouguer law (11) to give the Beer-Lambert law. Beer-Lambert's Law states that the incident light, I₀, is absorbed by a given material of thickness l, and concentration (of the analyte that absorbs light), c (mol/L), such that the exiting light is given by:

I=Iₒe^{-acl} (13)

which when expressed in log 10 notation gives:

I=ₒ10^{∈cl} (14)

where ∈ is the extinction coefficient and is a measure of how strongly a chemical species absorbs light (L/mol·cm).

Assuming very low concentrations (for example, such that ∈cl<0.05), the amount of light absorbed can then be approximated using the first term in the Maclaurin series (i.e. a Taylor series expansion of a function about 0j):

I_{abs}=Iₒ−I≅∈clIₒ ln 10 (15)

For fluorescence, the quantum yield, Q, is defined as the ratio of the number of photons emitted to the number of photons absorbed. Using this, the absorbed light energy and assuming the excitation source is completely attenuated, we can determine the released light energy as:

I_{emitted}=QI_{abs}≅Q∈clIₒ ln 10 (16)

From this, we can see that the energy emitted can potentially be increased by increasing the concentration, path length, the incident optical power, or by changing the fluorophore(which affects the quantum yield and extinction coefficient). Since the shot noise scales approximately as the square root of the light intensity, an increase in the optical power by a factor X, increases the signal-to-noise by a factor \sqrt{X}, thereby reducing requirements on detector and circuit sensitivity, assuming that other sources of noise are not dominant.

The second step is to determine the amount of emitted optical power reaching the sensor. Assuming a point source with isotropic emission in the middle of a microfluidic channel and integrating over the area of the photodetector, which may, for example, be assumed to have a square shape, divided by the total area of a sphere wrapped around the point source, the light collection efficiency is:

$$Collection efficiency = \frac{4 {r}^{2} {\int }_{0}^{{tan}^{- 1 ( \frac{o}{a} )}} {\int }_{0}^{{tan}^{- 1 ( \frac{o}{a} )}} d φ d θ}{4 π {r}^{2}} \qquad ( 17 )$$

Two additional factors may also be considered:

1. The analyte of interest, e.g. fluorophore, may be excited at a wavelength other than the wavelength for which it produces its maximum emission efficiency. This may not change the shape of the emission spectrum, however, the intensity of the emission is typically directly dependent on the amount of light the fluorophore absorbs. Thus, using a LED or even a laser where the spectral (band) characteristics do not match the fluorescence efficiency typically results in lower fluorescence emission. In some embodiments, the reduction in emission intensity may be assumed to be a scaling factor f1 for a particular analyte of interest.

2. If an optical filter 128 is used between the microfluidic structure 102 and the photodetector 126, the transmission characteristic of the filter 128 may need to be taken into account. In some embodiments, the transmission characteristic of the optical filter 128 for fluorescence light may be assumed to be a scaling factor f2 on collection efficiency of the photodetector.

With these final factors taken into consideration, the total light collected by the photodetector can be expressed as:

Total collected Light=(I_{emitted}×f1)×(collection efficiency×f2) (18)

Using equation (18) and the implementation specific details of the properties of the analyte of interest and the dimensions of the microfluidics and the photodetector, the total optical power reaching the photodetector may be determined.

The amount of optical power reaching the photodetector provides an idea of how sensitive the photodetector and its associated circuits need to be.

A brief description of a few examples of different photodetectors and the techniques used to facilitate low light optical detection will now be provided.

### Photodiodes

Some embodiments of the present invention may utilize a photodiode as a photodetector. Silicon microfabrication is one example of a semiconductor technology in which embodiments of the present invention might be implemented. Silicon photodiodes are solid-state devices that convert light energy into electrical energy. The photodiode regions are constructed when a p-type dopant (with acceptor impurities) is brought into contact with an n-type dopant (with donor properties).

With no externally applied bias, the concentration gradient formed by the large number of electrons in the n-type semiconductor, and large number of holes in the p-type semiconductor causes the electrons to diffuse into the p-type material and holes to diffuse into the n-type material. When the electrons and holes move to their respective sides, they leave behind immobile (i.e. part of the crystal lattice) positive and negative uncovered (ionized) dopant atoms respectively. An electric field forms between the positive and negative exposed ion regions (forming a built in potential), which quickly sweeps the carriers out, leaving the region depleted of free carriers (i.e. the depletion region).

An electron-hole pair is created when a photon of energy greater than the band gap of silicon 1.12 eV (λ<1100 nm−the infrared region of the electromagnetic spectrum) falls on the device and is readily absorbed. With the exception of carrier diffusion, only the light absorbed in the depletion region is used to generate the photocurrent. Furthermore, longer wavelengths of light have lower probability of being absorbed per depth traveling through silicon and therefore a greater fraction of the photons penetrate deeper as compared to shorter wavelengths.

The electron-hole pairs generated in the depletion region are swept by the electric field and if the two sides of the p-n junction are electrically contacted, an external current flows. Electron-hole pairs created from photons not absorbed in the depletion region diffuse for an average time called the carrier lifetime (determined by the purity of the silicon region), τ. If the carrier lifetime is short, the carriers quickly recombine and do not contribute to the photocurrent. However, if carriers are generated within a diffusion length, L of the depletion region, there is a high probability that they will be collected and will contribute to the photocurrent. The diffusion length is defined by:

L=\sqrt{Dτ}L (18)

where D is the diffusion coefficient. While typical values for the diffusion length, the carrier lifetime, and the diffusion coefficient, are respectively 1-100 μm, 1-10,000 ns and 12 cm²/s (for holes) and 34 cm²/s (for electrons), specific values are related to the doping concentration level.

There are two modes of operation for silicon photodiodes, photovoltaic (PV) and photoconductive (PC). In photoconductive mode, the diode is reverse biased and acts like a current source, while in photovoltaic mode, the diode is not biased and exhibits nonlinear characteristics (as the diode becomes forward biased) with very bright light conditions or large load resistance.

The output current of the photodetector can be expressed by:

$${I}_{o} = {I}_{ph} - {I}_{S} ( {e}^{( \frac{qV}{nKT} )} - 1 ) - {I}_{shunt} \qquad ( 19 )$$

In equation (19), the second term represents the diode current , I_{S} is the photodiode reverse saturation current, q is the electron charge, k is Boltzmann's constant, T is the absolute temperature of the photodiode, Iₚₕ is the photocurrent under illumination, and Iₛₕᵤₙₜ is the current through a non-ideal shunt resistance. There are two major currents which contribute to the shunt resistance, diffusion currents in photovoltaic mode and drift currents in photoconductive mode.

If the terminals of the photodiode are shorted, a photocurrent, I_{SC}, proportional to the total output current given in (19) flows from the anode to the cathode of the photodiode and when the circuit is open, an open circuit voltage, V_{OC}, is generated with positive polarity at the anode. With no external bias applied across a photodiode, the photodiode exhibits a built-in voltage given as a function of the doping concentrations of the p and n side of the junctions (but which is not measurable because of contact voltages which exactly balance this built-in voltage). It is this built-in electric field that separates the electron-hole pairs generated from absorbed photons. Because the electric field that separates the generated electron-hole pairs can at most provide the built-in voltage, the open-circuit voltage is then bound at most by this value.

The choice of PC or PV mode operation may depend on several factors:
PC mode exhibits a large (higher than nine orders of magnitude) linear range of operation with increasing illumination. PV mode however has a limited linear range of operation, which can be extended by decreasing the load resistance or by measuring the short-circuit current, I_{SC}, by connecting the photodiode to an active circuit which produces a virtual ground.
The response time is dependent on the RC time constant defined by the diode capacitance and load resistance. Under the application of a reverse bias (in the PC mode), the depletion width is increased reducing the capacitance and the response time.
Defects in the silicon crystal lattice result in trap sites in the forbidden energy gap (the region between the valence and conduction bands) and correspondingly act as generation-recombination centers, producing current. This current is generated in the depletion region and is proportional to the junction area and depletion region width. It is this current in combination with the diffusion current (which saturates at I_{S} under the application of a reverse bias) that results in a so called dark current, which acts to limit the low light sensitivity of PC mode photodiodes. In PV mode, as no bias is applied, the dark current is theoretically zero, allowing for high signal to noise ratio (SNR) in low light conditions. In addition, there are two other factors, band-to-band tunnelling and thermionic emission currents, which also contribute to the dark current. However, their contributions are typically small.

To determine the response of a photodiode to different wavelengths and its lower limit of detection (LLOD), the concepts of responsivity, quantum efficiency, and the noise equivalent power (NEP) are now briefly described.

One parameter that may be considered when dealing with photodiodes is responsivity, R, defined as the current (Iₒ) generated for each received watt of incident optical power (Φ) with units of ampere per watt (A/W). In the ideal case, each incident photon generates an electron-hole pair and:

$${R}_{ideal} = \frac{{I}_{o}}{Φ} = \frac{q λ}{hc} \qquad ( 20 )$$

where λ is the wavelength of the incident light, h is Planck's constant, and c is the speed of light. However, in some cases, the responsivity for real silicon photodiodes deviates from the ideal case (in some cases, by about 30%). The initial reduction is due to photons that are reflected from the surface, never penetrating the material and thus never reaching the depletion region. For the case of normal incidence, this reflection coefficient (R) (assuming light passing from air into a material of refractive index (n) can be calculated using Fresnel's equation:

$$R = {( \frac{{n}_{1} - {n}_{2}}{{n}_{1} + {n}_{2}} )}^{2} \qquad ( 21 )$$

For silicon, with n≈3.5, the reflection coefficient is 31%, leaving only 69% of the light left to penetrate into the detector material. This is mirrored in the near 30% reduction of responsivity from the ideal 100% quantum efficiency case (i.e. where one photon generates one electron-hole pair). In addition to this reduction due to the interface, at short wavelengths (i.e., less than 380 μm) and at wavelengths greater than 1.1 μm, there is a further minor and steep fall-off of responsivity respectively. The minor reduction is because the photons are absorbed too near to the surface, which prevents the generated electron-hole pairs from contributing to the photocurrent as they are not near enough to the electric field of the deeper depletion region to be swept in. The steep fall-off on the other hand, is because the photons have insufficient energy to overcome the bandgap of the semiconductor (e.g. 1.12 eV for silicon) and consequently pass through the crystal. Such deviations of the actual from ideal responsivity is called quantum efficiency (q):

$$η = \frac{{R}_{actual}}{{R}_{ideal}} = \frac{{I}_{o} hc}{Φ λ} \qquad ( 22 )$$

and represents the ratio of the number of electron-hole pairs which contribute to the generated photocurrent, to the number of incident photons.

Responsivity and quantum efficiency help establish the amount of current that is generated for a given incident light power. However, to quantify the limit of detection, it may be useful to examine the noise sources present in a photodiode. There are three main sources of noise in photodiodes, thermal (or Johnson noise, I_{J}), shot noise (I_{S}), and flicker noise (I_{F}). Since these sources are independent of each other, the total noise current can be expressed by:

Iₙ=\sqrt{I_{J}²+I_{S}²+I_{F}²} (23)

Thermal noise is generated by the random thermal motion of electrons and is present in any linear passive resistor. For the photodiode, the thermal noise contribution comes from the shunt resistance (Rₛₕ) and is expressed as:

$$\frac{{I}_{J}}{\sqrt{B}} = \sqrt{\frac{4 kT}{{R}_{sh}}} \qquad ( 24 )$$

where k is Boltzmann's constant (1.38×10-23 J/K), T is the absolute temperature (K), and B is the noise bandwidth (Hz). Most often, since the thermal noise is independent of frequency, it is expressed in units of A/√Hz.

Shot noise is generated by random fluctuations in the normal current flow through a P-N junction. Since the flow of carriers is subject to random movements, a noise current is generated. Because it is independent of frequency, similar to thermal noise, it can be expressed in units of A/√Hz and is given by (where q is the electron charge):

$$\frac{{I}_{S}}{\sqrt{B}} = \sqrt{2 q ( {I}_{ph} + {I}_{dark} )} \qquad ( 25 )$$

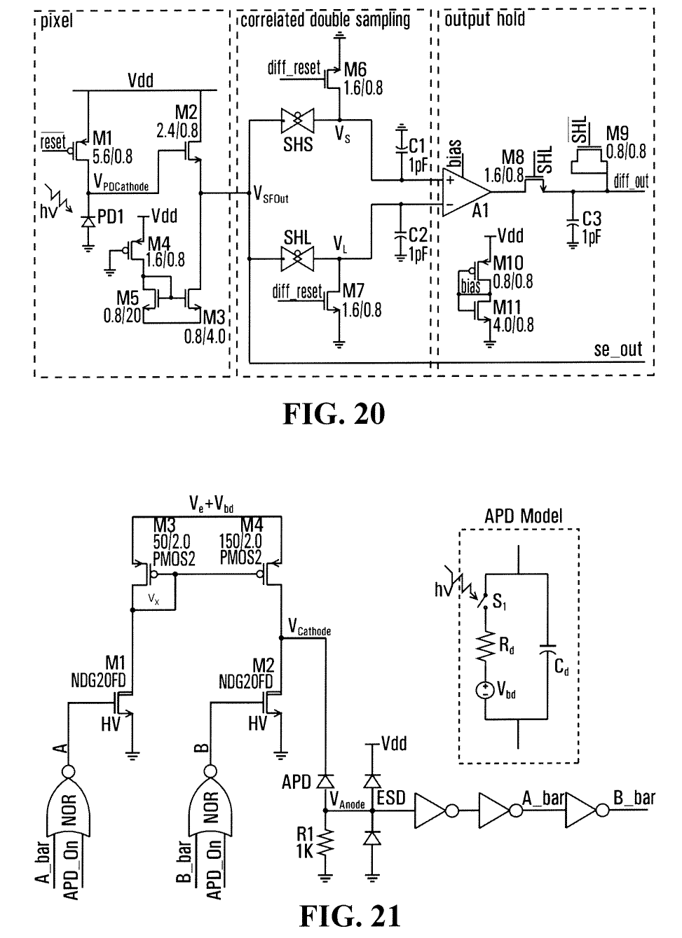

In some embodiments, as described later with respect to FIG. 20, a transimpedance amplifier may be included in optical detection component 108 in conjunction with a PC mode photodiode. For an integrating transimpedance amplifier, the shot noise equation above can be expressed using the integration time, Tᵢₙₜ, and even more intuitively as proportional to the number of electrons generated due to incident photons as:

$${I}_{S} = \sqrt{\frac{2 q ( {I}_{ph} + {I}_{dark} )}{{T}_{int}}} = q \sqrt{2 ( num . electrons )} \qquad ( 26 )$$

For flicker (1/f) noise, the mechanisms behind it are not very well understood in the art. A general equation to represent this type of noise has been determined experimentally and is given by:

$$\frac{{I}_{F}}{\sqrt{B}} = \sqrt{\frac{{KI}_{dc}}{f}} \qquad ( 27 )$$

where K is a constant that depends on the type of material and geometry, I_{dc} is the dc junction current and f is the frequency. Flicker noise dominates when the bandwidth of interest contains frequencies less than about 1 kHz.

The lower limit of detection for a photodiode can then be expressed as the intensity of incident light required to generate a current equal to the total noise currents (IN). This limit is called the Noise Equivalent Power (NEP) and is defined over a frequency of interest by:

$$NEP = \frac{{I}_{N}}{R} \qquad ( 28 )$$

where R is the responsivity (A/W).

In some embodiments, photodetector 126 is implemented, at least in part, with a photodiode. Examples of photodiode implementations that may be included in some embodiments of the present invention will now be discussed with reference to FIGS. 18A-18E.

The photodiodes illustrated in FIGS. 18A to 18E were designed for DALSA Semiconductor's three metal layer, triple well, dual gate oxide 0.8-μm 5V/HV CMOS/DMOS (double diffused MOS) process, and are merely provided for illustrative purposes.

FIG. 18A is a cross-sectional view of an p+/Deep N-Well photodiode, in accordance with an embodiment of the present invention. The anode of this photodiode is the p+ diffusion and the cathode is the Deep N-Well. This configuration allows for substrate-isolated optical detectors as it can be placed in its own separate Deep N-Well. Since the p+ diffusion has a much larger doping concentration than the Deep N-Well, the depletion region extends mostly into the lighter doped Deep N-Well, with a depth slightly greater than 0.3 μm (i.e. between the p+ diffusion and the Deep N-Well). The designed active area is 50 μm×50 μm and the N-Well contacts are placed a minimum distance away from the p+ diffusion, as allowed by the fabrication process in which the photodiode was fabricated. This photodiode has an active area of 50 μm×50 μm.

FIG. 18B is a cross-sectional view of a P-Well/n+ photodiode, in accordance with an embodiment of the present invention. The anode of this device is the P-Well and the cathode is the n+ diffusion. This device also allows for isolation since it is in its own P-Well. The depletion region extends into the lighter doped P-Well and the depth of the junction between the n+ diffusion and the PWell is about 0.4 μm. This photodiode has an active area of 150 μm×150 μm.

FIG. 18C is a cross-sectional view of an P-Epi/Deep N-Well photodiode, in accordance with an embodiment of the present invention. The anode is the P-Epi layer and the cathode is the Deep N-Well. The depletion region extends mostly past the Deep N-Well and into the lighter doped P-Epi region with the junction depth surpassing 6.0 μm. This photodiode has an active area of 150 μm×150 μm.

FIG. 18D is a cross-sectional view of an P-Epi/HV N-Well photodiode, in accordance with an embodiment of the present invention. Once again, the anode is the P-Epi layer, however in this case the cathode is the HV N-Well. The HV N-Well is shallower than the Deep N-Well extending only 4.5 μm deep. The depletion region extends once more into the lighter doped p-epitaxial layer. This photodiode has an active area of 150 μm×150 μm.

FIG. 18E is a cross-sectional view of an P-Base/HV N-Well photodiode, in accordance with an embodiment of the present invention. The anode is the P-Base layer and the cathode is the Deep HV N-Well. With the higher doping profile of Pbase, the depletion region extends into the HV N-Well from about a depth of 1.2 μm. This photodiode was also implemented with an active area of 150 μm×150 μm.

### Avalanche Photodiodes

With internal gain, avalanche photodiodes (APDs) are silicon photodiodes which exhibit quantum efficiencies greater than 100%. Thus, in low light conditions, where the noise of the amplifier can exceed the noise of the amplified signal, avalanche photodiodes provide an excellent alternative to standard photodiodes by reducing the need for such a high-gain (and possibly noisy) amplifier.

APDs are operated in two main modes. In the linear mode of operation, APDs are operated below their breakdown voltage, and the applied electric field determines a level of internal gain (i.e. the number of electronhole pairs generated per incident detected photon). Operated in ‘Geiger-mode’, silicon APDs allow for single-photon detection and hence are also called Single Photon Avalanche Photodiodes (SPADs). Shallow junction Geiger-mode APD detectors have been manufactured with CMOS compatible processing steps, however, their operation requires much higher reverse bias voltages than standard silicon photodiodes operated in PC mode. Generally higher gain is achievable at lower voltages with ‘Geiger-mode’ APDs.

During design, APDs are generally modeled using either equation based analytical models or by solving physical equations using numerical or measurement based equivalent circuit methods.

Similar structures can be used for both linear and Geiger mode APDs. However, for Geiger-mode APDs, the active area is typically reduced to limit thermal generation (and allow proper single photon detection operation).

For Geiger-mode, by applying a reverse bias in excess of the breakdown voltage of the device, a single electron-hole pair created by an incident photon (or thermally generated under dark conditions) in the depletion layer experiences a self-sustaining avalanche multiplication effect (impact ionization). By reducing the reverse voltage below the breakdown potential, the device can be “quenched,” preventing damage due to high power (heating effects), by ending the avalanche event. This is typically accomplished using either a passive quenched circuit (PQC) which simply consists of a resistor in series with the APD or an active quenched circuit (AQC). PQCs are typically only adequate for low count rates (<105/s) due to the time constant delay (of the quenching resistor and detector capacitance), while AQCs are used for higher count rates (e.g. many GHz) as the circuits can be optimized to reduce dead-times (i.e. time to place the APD in a reverse bias state after quenching). In some AQC circuits, the APD anode is biased at a large negative potential (−V_{NN} which is dependent on the specific APD but can range from 20V-180V) to allow LV components to be used in the quenching circuit.

Because of the high voltages required for Linear and Geiger Mode APDs, the design of such components is typically more involved than standard P-N junction photodiodes.

One issue is the higher electric fields which appear at the junction edges. For proper avalanche operation, the highest electric field should be confined to the center of the diode. However, since:

1. The highest electric field is present at the edges because of the non-planar, spherical geometry of the junction and

2. Breakdown occurs in the region (i.e. edges) where breakdown is first reached it becomes difficult to contain the highest electric field to the center of the diode as the edges (and hence the junction) breakdown at lower fields first. If the doping concentration, N, is given, the exact breakdown voltage of different junctions and the width of the depletion region can be determined. This information may be useful in modeling devices such as APDs, photodiodes, and zener diodes as breakdown voltages for the different junction combinations can be easily calculated (e.g. for APDs and zener diodes) and the exact depth for greatest sensitivity (to specific wavelengths) can be determined (e.g. for photodiodes).

When the dopant concentration (N) in a semiconductor changes abruptly from acceptor, NA, to donor dopants, ND, there is an abrupt junction. In particular if NA>>ND (or vice versa), a one sided abrupt p⁺-n (or n⁺-p) junction forms.

Assuming a one-sided abrupt P-N diode, the corresponding breakdown voltage can be determined using:

$${V}_{br} = \frac{{ɛ}_{S} {E}_{m}^{2}}{2 qN} \qquad ( 29 )$$

where Eₘ is the electric field (V/m) at breakdown for a Si P-N diode (at room temperature) and is defined by:

$${E}_{m} = \frac{4 \times {10}^{5}}{1 - \frac{1}{3} {log}_{10} ( \frac{N}{{10}^{16}} )} \qquad ( 30 )$$

The corresponding depletion region width equals:

$${w}_{br} = \frac{{ɛ}_{S} {E}_{m}}{2 qN} \qquad ( 31 )$$

The equations above are given for a one-sided abrupt junction and in reality, linearly graded or diffused junctions with curvature have reduced breakdown voltages.

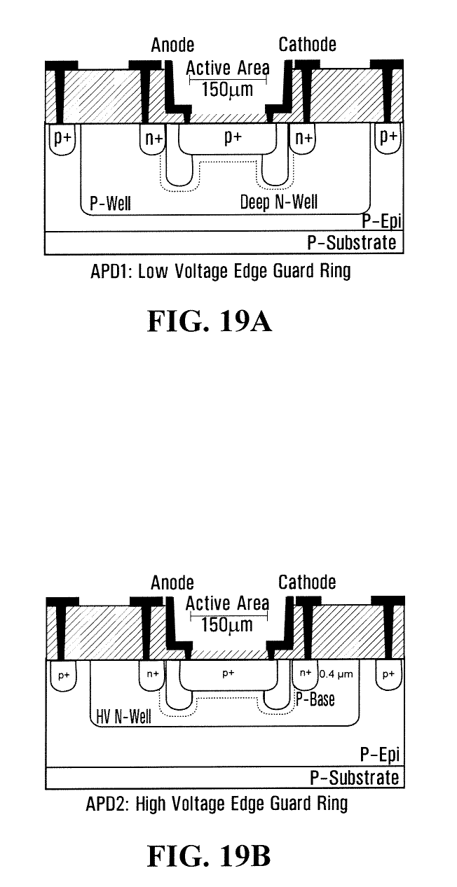

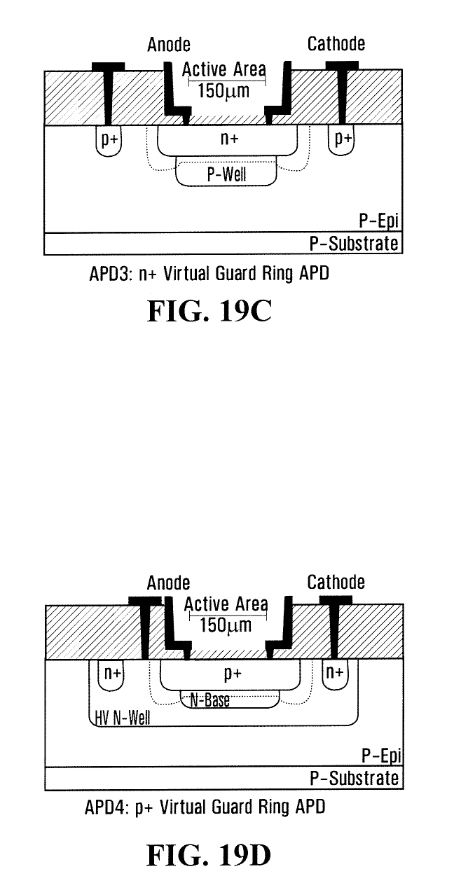

In some embodiments, photodetector 126 is implemented, at least in part, with an avalanche photodiode. Examples of avalanche photodiode implementations that may be included in some embodiments of the present invention will now be discussed with reference to FIGS. 19A-19D.

The photodiodes illustrated in FIGS. 19A to 19D were designed for DALSA Semiconductor's three metal layer, triple well, dual gate oxide 0.8-μm 5V/HV CMOS/DMOS (double diffused MOS) process, and are merely provided for illustrative purposes.

Even though the breakdown voltage is inversely proportional to the doping density, a circuit designer does not have direct control over this property. There are however two common methods of addressing edge breakdown and they include either using periphery guard rings or by using a virtual guard ring:

1. By placing low-doped guard ring regions at the periphery, premature breakdown of the edges can be suppressed allowing for higher electric fields at the center of the junction.

2. By placing a highly doped region (n-base doping >n-well doping) at the center of the diode (FIG. 4.21b), a lower breakdown voltage region is established, allowing for proper (center breakdown) avalanche operation.

These two corresponding methods were used in the design of the four different avalanche photodiode structures illustrated in FIGS. 19A-19D, but the same structures can also be used in the design of zener diodes.

Using the two methods, four different designs were possible: two (one edge guard ring design and the other using the virtual guard ring) using the low-voltage well and two (one edge guard ring design and the other using the virtual guard ring) using the high-voltage well.

The first two designs use lighter doped (higher breakdown voltage) guard rings at the edges of the anode junction. The APD shown in FIG. 19A is in the deep N-Well for low voltage operation while the APD in FIG. 19B is implemented in the HV N-Well for higher voltage (and thus generally superior avalanche) operation. In the fabrication process used to manufacture the APDs shown in FIGS. 19A-19D, the p+/Deep N-Well breakdown voltage is 13V and the p+/HV N-Well is 18 V.

If these are the potentials at which the edge breaks down first, then the center of the junction never reaches these voltages. However, since, in the fabrication process that was used, the P-Well/DeepN-Well and P-Base/HVN-Well breakdown voltage is 40V, by adding guard ring structures to the junction periphery, higher electric fields are achieved at the center of the APDs. Similarly, by placing a virtual guard ring at the center of the junction, as was done in the APDs shown in FIGS. 19C and 19D, the depletion region width is extended around the edges allowing for higher electric fields at the center of the APDs shown in FIGS. 19C and 19D.

The active areas of the APDs shown in FIGS. 19A-19D were designed to be 150 μm×150 μm to match the width of the microfluidic channel that would be post-processed overtop of the photodetector.

The design of the silicon photodiode based optical detection circuit involved addressing several problems:
Low light conditions: the estimated optical power reaching, for example, a 150 μm×150 μm photodiode is about 30.4 pW (calculated in accordance with equation (18)). Such low light conditions translate to low (picoamp) photocurrents.
Significantly higher or lower optical powers: designing for a specific range (e.g. based on calculation results) limits the circuit adaptability. Depending on the size of the analyte passing by the detector, the detected light may be an order larger or smaller than the calculated value.
Photodiode mode of operation: PV offers low noise operation. PC mode theoretically offers slightly higher QE (due to the larger electric field from the resulting wider depletion region) in exchange for a larger dark current contribution.
Noise: 1/f noise dominates at low frequencies (See equation (27)).

FIG. 20 is a schematic of a photodiode based optical detection circuit that may be used to implement the photodetector 128 and transimpedance amplifier 124 of the optical detection component 108 shown in FIG. 1.

The circuit shown in FIG. 20 is a three stage design. The first (pixel) block is responsible for photocurrent-voltage integration followed by buffering the voltage before it is passed to the next stage. The second stage stores the voltage from two different states, a dark and light state respectively. The third stage subtracts the two (i.e. the dark current contributions from the signal of interest) voltages using a differential amplifier, A1, then stores and holds the final result at the output stage for further processing.

The pixel block is composed of three main transistors: a reset (M1), source-follower buffer (M2) and a load transistor (M3), along with support transistors (M4 and M5). On reset, the photodiode voltage is precharged to V_{dd} by pulsing M1 (designed with a large width). Once reset, as light falls on the photodiode, the V_{PDCathode} node capacitance discharges through the generated photocurrent (leaving the photodiode anode). M2 buffers (with its high input impedance) and “tracks” this discharging node at its output. By ensuring constant current flow through M2 (by limiting the sink capability of M3 with a longer transistor design), the input/output response of the source follower (M2) is made as linear as possible, while ensuring low current draw. Because the photodiode is operated in PC mode, dark current is a continuously contributing factor (even in the absence of light), discharging V_{PDCathode}.

Furthermore, ambient background light (which can be minimized by using a dark enclosure), which is typically present even if there is no fluorescently tagged analyte passing the detector, also acts to skew the measured results. This background ambient light may be reduced by placing the device in a dark enclosure. By sampling the contributions from the dark current and ambient light sources, and subtracting their combined effect from the actual signal, these additional “noise” sources can be differentially eliminated. This is accomplished by the second (CDS) stage.

Correlated double sampling is a two step operation, first the “dark” (with no excitation source) then the “light” (with emitted light source) value is sampled, then the two are subtracted from each other respectively. In some embodiments, this “smart” sampling is possible because the digital control logic for this circuit is also responsible for controlling and/or coordinated with the excitation light source (e.g. LED or laser).

Initially with the excitation source (not shown) on, the reset transistor (M1) is pulsed and the “light” current is integrated (through the discharge of V_{PDCathode}) over a fixed period of time. At the end of this, the SHS pass-transistor is driven high and the corresponding sampled (V_{SFout}) value is stored on C1. Afterwards, the excitation source turns off, M1 is pulsed, and the “dark” state (with its dark current and ambient light contributions) is integrated for the same amount of time. At the end of this period, the pixel stage output (VSFOut) is sampled by driving SHL high and its value stored on C2. At the same time that SHL is high, M8 in the third stage shunts the differential output of the amplifier to C3 for storage and later processing (e.g. by an ADC). Because this processing may be done on-chip, without the need to transmit the signals over a potentially noisy transmission line off-chip for processing, the analysis can potentially be of a high precision and sensitivity.

Additionally, since flicker noise is inversely related to frequency:

$$\overline{{V}_{n}^{2}} = \frac{K}{{C}_{ox} WL} \times \frac{1}{f} \qquad ( 32 )$$

by implementing an integrating transimpedance (versus a non-integrating-high gain) amplifier, we can suppress the effects of flicker noise by operating at higher frequencies.

Using the equation for the 1/f noise corner frequency:

$${f}_{C} = \frac{K}{{C}_{ox} WL} {g}_{m} \frac{3}{8 kT} \qquad ( 33 )$$

It is possible to measure what part of the frequency band is most corrupted by flicker noise and try to remain outside of that range.

For the fabrication process in which prototypes have been fabricated, the flicker coefficient K=1.622×10-28V2F (DALSA model files for cmosp8g V2P5), the corner frequency is calculated to be about 1.43 kHz. Past this point, the flicker noise contribution falls off significantly and the thermal noise determines the noise floor.

Another design consideration in this circuit is regarding the problem of charge injection and clock feedthrough in the three sampling sub-circuits (i.e. the two pass transistors and M8 along with their associated capacitors).

Charge injection results when a switch turns off, and half of the charge exiting the collapsing channel (in the inversion layer) is absorbed by the sampling capacitor and the other half is absorbed by the input source. The total charge in the inversion layer can be expressed by:

Q_{ch}=WLCₒₓ(V_{DD}−Vᵢₙ−V_{TH}) (34)

and the resulting error voltage (assuming half of Q_{ch} is injected into a sampling capacitor C_{H}) equals:

$$Δ V = \frac{{WLC}_{ox} ( {V}_{DD} - {V}_{in} - {V}_{TH} )}{2 {C}_{H}} \qquad ( 35 )$$

This contributes three types of errors on the output voltage, two of which are expressed by:

$${V}_{out} = {V}_{in} ( 1 + \frac{{WLC}_{ox}}{{C}_{H}} ) - \frac{{WLC}_{ox}}{{C}_{H}} ( {V}_{DD} - {V}_{TH} ) \qquad ( 36 )$$

where the first term represents a non-unity gain and the second term represents a constant offset voltage. The third error is because of the nonlinear dependence of V_{TH} on Vᵢₙ (body effect).

Thus, by using pass transistors in the second stage, the opposite charge packets injected by the collapsing inversion layer of the complementary switches (holes for the PMOS and electrons for the NMOS) will cancel each other out (i.e. when Δq1=Δq2), reducing the effects of charge injection. However, this occurs only at one input level (i.e., calculated here as Vᵢₙ≈2.42V) defined by:

W₁L₁Cₒₓ(V_{CK}−Vᵢₙ−|V_{THN}|)=W₂L₂Cₒₓ(Vᵢₙ−|V_{THP}|) (37)

The differential nature of the circuit also helps remove the constant offset and lowers the nonlinear component of charge injection.

Clock feedthrough introduces an error by coupling the clock transitions to the sampling capacitor through its gate-drain or gate-source overlap capacitance. Clock feedthrough error is expressed by the capacitive voltage divider equation given by:

$$Δ V = {V}_{CK} \frac{{WC}_{ov}}{{WC}_{ov} + {C}_{H}} \qquad ( 38 )$$

and can be suppressed using a dummy switch, M9, with W_{dummy}=0.5W_{actual} and L_{dummy}=L_{actual}. Furthermore, assuming that half of the charge leaving M8 enters the amplifier and the other half enters C3, the same dummy transistor (as long as it is clocked on the opposite edge) reduces the effects of charge injection of M8 on C3 by absorbing the injected charge, instead of C3.

While FIG. 20 provides one example of a photodiode-based optical detection component that may be used in some embodiments of the present invention, FIG. 21 is a schematic of an exemplary avalanche photodiode quenched circuit that may be used in some embodiments of the present invention.

The example circuit shown in FIG. 21 is an active quenched circuit (AQC) for single photon detection, e.g. Geiger mode. For Geiger mode avalanche photodiode circuits, passive quenched circuits offer slower response due to the RC delay from the series resistor and APD capacitance. Therefore, with a low expected, e.g. 30.4 pW of optical power (Φ) arriving at the detector, about 91.8 million photons/sec are calculated to strike the APD (assuming an emission wavelength of 600 nm for the ROX fluorophore) based on:

$$Number of Photons \text{/} sec = \frac{Φ λ}{hc} \qquad ( 39 )$$

where h is Planck's constant (6.626×10−³⁴ J·s) and c is the speed of light. As a result of this high count rate, an active quenched circuit architecture may be used in some embodiments of the present invention, such as the illustrative embodiment shown in FIG. 21.

The circuit illustrated in FIG. 21 consists of a mix of LV digital and HV analog components and was designed for the DALSA semiconductor fabrication process discussed earlier. The avalanche photodiode model that was used for simulation is also shown in FIG. 21.

The switch (S₁) closes when a photon of light strikes the APD and only opens once the voltage across the APD decreases below its breakdown voltage (V_{bd}).

For single photon (i.e. Geiger mode) detection, the APD is operated at an excess voltage plus the breakdown voltage (Vₑ+V_{bd}). Avalanche breakdown probability increases with increasing excess voltage up to a saturation point, however in some cases an excess voltage of only a few volts is required. Here, an excess voltage of 2V was selected, yielding a maximum applied voltage of 15V (to also relate back to the drain-source breakdown of the PMOS2 used in the circuit).

Because of the high voltage requirements, APD On is used as on/off logic. With APD On high, both HV LDMOS transistors M1 and M2 are off, thus reducing power consumption. In operation, with APD On driving low, the node A is initially high (and complementary input B is low) since with no photons striking the APD, only a small amount of reverse bias current leaks through the diode, insufficient to pull V_{Anode} high (and A respectively low). This maintains the V_{Cathode} at Vₑ+V_{bd}. Once a photon strikes the APD and avalanche breakdown is triggered, the APD begins to conduct a large amount of current, limited only by amount of current M4 can source (in this case, about 3.5 mA), generating sufficient voltage on R1 to trigger the series of inverters.

This pulse pulls A Bar high and B Bar low (and inversely, A low and B high). With Mich. off, M4 also turns off, shutting off the supply to the APD. Also, with B high, M2 helps to further drive the V_{Cathode} node low, enabling a rapid quenching of the APD. Once current no longer passes through the APD, A turns on (B off), and with M4 sized with a larger width, the circuit is quickly charged and placed back into its starting state (i.e. APD biased at Vₑ+V_{bd}).

The dead time is defined as the time during which the APD is not operating in single photon detection mode (because it is not biased above its breakdown voltage). It is the sum of the quenching plus recharge time (i.e. for the voltage to reach about 99% of the Ve+Vbd) and it places an upper limit on the operating speeds of the circuit. From simulation, the dead time is measured to be about 10 ns, thus allowing the circuit to operate up to about 100 MHz (meeting the specification of about 91.8 MHz).

Though this circuit actively quenches the APD to ensure it meets the operating requirements in a unique manner, there are other circuits presented in literature capable of operating at higher frequencies. However, because conventional LV AQCs limit the excess voltage that can be placed on the APD (by the drain-source breakdown voltage of the LV components), by using high voltage components with much larger breakdown voltages, a larger excess voltages can be used and the detection probability of the APD can potentially be increased.

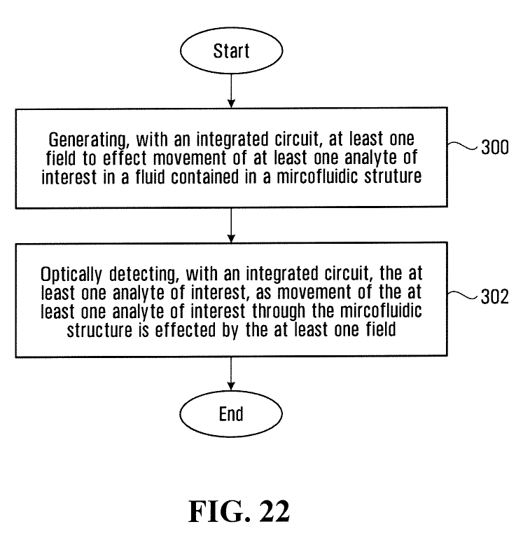

An example of a method in accordance with an embodiment of the present invention will now be described with reference to FIG. 22.

FIG. 22 is a flowchart of a method in an integrated circuit for manipulating and detecting an analyte in a microfluidic system, in accordance with an embodiment of the present invention.

The method is carried out by the integrated circuit, and includes, at block 300: generating at least one field to effect movement of at least one analyte of interest in a fluid contained in the microfluidic structure.

Step 302 involves optically detecting the at least one analyte of interest, as movement of the at least one analyte of interest through the microfluidic structure is effected by the at least one field.

In some embodiments, generating at least one field comprises controlling a field generating component on the integrated circuit to generate the at least one field.

In some embodiments, optically detecting the at least one analyte of interest comprises detecting fluorescence light emitted by the at least one analyte of interest upon excitation of the at least one analyte of interest with excitation light.

In some embodiments, detecting fluorescence light emitted by the at least one analyte of interest comprises optically filtering light between the microfluidic structure and the integrated circuit to reduce intensity of excitation light reaching the integrated circuit.

In some embodiments, optically detecting the at least one analyte of interest comprises optically detecting the at least one analyte of interest in the fluid contained within the microfluidic structure without an intervening waveguide or lens.

In some embodiments, generating said at least one field comprises generating at least one electric or magnetic field having a sufficient strength to interact with the at least one analyte of interest in the microfluidic structure.

In some embodiments, generating said at least one electric or magnetic field includes generating a sufficient voltage or current for generation of the at least one electric or magnetic field, switching the generated voltage or current from the voltage or current generating component, and outputting the voltage or current from at least one output to generate the at least one electric or magnetic field.

In some cases, the integrated circuit also generates the excitation light with an on-chip light source, such as an LED.

In some embodiments, the integrated circuit coordinates generation of the excitation light with detection of the fluorescence light emitted by the at least one analyte of interest. In some cases, this coordination may be used in conjunction with the “smart” sampling of a three stage optical detection components, such as the exemplary embodiment shown in FIG. 20.

In some embodiments, the method further includes the integrated circuit communicating with a processor that is external to the integrated circuit.

As noted above, miniaturization and integration of microfluidics with microelectronics and optoelectronics has been hindered by reliance on large and expensive external components for field generation and/or optical detection. Prototypes in accordance with embodiments of the present invention have been fabricated using a microfluidic-compatible semiconductor fabrication process available from DALSA Semiconductor that allows the integration of microelectronic dimension polymer microfluidic channels on top of high voltage CMOS (HVCMOS) wafers, with top-metal electrodes coated with a bio-compatible film of palladium.

In this process, fabrication of a microfluidic structure involves the patterning of a microchannel floor and walls within a thick (5 to 20 μm) photo-sensitive epoxy-based polymer onto which a polymer roof is wafer level-bonded via a carrier wafer. The carrier wafer is later debonded from the HVCMOS wafer by a stiction-free removal process of a sacrificial layer. Openings in the polymer floor layer provide contact between the HVCMOS electrodes and the media in the microfluidic channels.

An integrated circuit chip, in accordance with the block diagram shown in FIG. 1 was designed in DALSA Semiconductor's three metal layer, triple well, dual gate oxide 0.8-μm 5V/HV CMOS/DMOS (double diffused MOS) process. This mixed voltage process was chosen because it combines 5V mixed mode CMOS with the 300V transistors for generation of field strengths sufficient to interact with samples contained in the microfluidic structure.

The foregoing description includes many detailed and specific embodiments that are provided by way of example only, and should not be construed as limiting the scope of the present invention. Alterations, modifications and variations may be effected to the particular embodiments by those of skill in the art without departing from the scope of the invention, which is defined solely by the claims appended hereto.

1. An integrated circuit operable in association with a microfluidic structure, said integrated circuit comprising:
a field generator;
a controller configured to control the field generator to generate at least one field to effect movement of at least one analyte of interest in a fluid contained in the microfluidic structure; and
an optical detection component configured to optically detect the at least one analyte of interest, as movement of the at least one analyte of interest through the microfluidic structure is effected by the at least one field.

2. The integrated circuit of claim 1, wherein the optical detection component comprises a photodetector configured to detect fluorescence light emitted by the at least one analyte of interest upon excitation of the at least one analyte of interest by excitation light from an excitation light source.

3. The integrated circuit of claim 2, wherein said photodetector is configured to detect the fluorescence light emitted from the at least one analyte of interest in the microfluidic structure with sufficient sensitivity to resolve the at least one analyte of interest in the fluid.

4. The integrated circuit of claim 2, wherein said controller is further configured to control the optical detection component to detect fluorescence light emitted from the at least one analyte of interest in the microfluidic structure.

5. The integrated circuit of claim 1, wherein the optical detection component comprises a photodetector configured to detect light emitted by the at least one analyte of interest and circuitry configured to digitize an output of the photodetector.

6. The integrated circuit of claim 5, wherein the circuitry configured to digitize an output of the photodetector comprises an amplifier configured to amplify an output of the photodetector and an analog-to-digital converter configured to convert the amplified output of the photodetector to a digital value.

7. The integrated circuit of claim 2, wherein the optical detection component further comprises an optical filter, located between the microfluidic structure and the photodetector, configured to reduce intensity of excitation light from the excitation light source that reaches the photodetector.

8. The integrated circuit of claim 1, wherein the optical detection component is configured to optically detect the at least one analyte of interest in the fluid contained within the microfluidic structure without an intervening waveguide or lens.

9. The integrated circuit of claim 1, wherein said field generating component comprises at least one component configured to generate at least one electric or magnetic field having a sufficient strength to interact with the at least one analyte of interest in the fluid to effect movement of the at least one analyte of interest.

10. The integrated circuit of claim 9, wherein said at least one component configured to generate at least one electric or magnetic field comprises:
a voltage or current generating component configured to generate a sufficient voltage or current for generation of the at least one electric or magnetic field;
a switching component configured to switch the generated voltage or current from the voltage or current generating component; and
an output component configured to generate the at least one electric or magnetic field from the generated voltage or current.

11. The integrated circuit of claim 10, wherein said voltage or current generating component comprises a DC-DC converter, said DC-DC converter being any one of:
capacitive or inductive.

12. The integrated circuit of claim 10, wherein said switching component comprises a level-shift circuit connected to an output driver.

13. The integrated circuit of claim 1, wherein said field generating component comprises a level-shift circuit connected to an output driver.

14. The integrated circuit of claim 10, wherein said output component comprises at least one electrode or integrated electromagnet, configured to generate the at least one electric or magnetic field from the generated voltage or current.

15. The integrated circuit of claim 1, wherein said controller comprises at least one of: an analog-to-digital converter (ADC) or a digital-to-analog converter (DAC).

16. The integrated circuit of claim 1, wherein the integrated circuit further comprises an electrochemical detection component configured to detect at least one electrochemical property of the fluid.

17. The integrated circuit of claim 1, wherein the integrated circuit further comprises a conductivity detector configured for contactless capacitive coupling with the microfluidic structure to detect a conductivity of the fluid.

18. The integrated circuit of claim 1, wherein the controller is further configured to communicate with a processor.

19. The integrated circuit of claim 1, wherein said microfluidic structure comprises at least one of the following:
at least one microfluidic channel; and
at least one reservoir.

20. The integrated circuit of claim 1, wherein said integrated circuit is fabricated using one of the following semiconductor fabrication techniques: Si, SiGe, CMOS, GaAs, InP, SOI.

21. The integrated circuit of claim 1, wherein said optical detection component comprises at least one of: a photodiode, an avalanche photodiode, a Positive-Intrinsic-Negative (PIN) photodiode, a phototransistor, and a Charge-Coupled-Device (CCD).

22. The integrated circuit of claim 1, wherein the optical detection component comprises an avalanche photodiode operable in single photon detection mode.

23. An apparatus comprising:
a microfluidic structure; and
an integrated circuit according to claim 1 operable in association with the microfluidic structure.

24. A method in an integrated circuit operable in association with a microfluidic structure, said method comprising:
generating at least one field to effect movement of at least one analyte of interest in a fluid contained in the microfluidic structure; and
optically detecting the at least one analyte of interest, as movement of the at least one analyte of interest through the microfluidic structure is effected by the at least one field.

25. The method of claim 24, wherein generating at least one field comprises controlling a field generating component on the integrated circuit to generate the at least one field.

26. The method of claim 24, wherein optically detecting the at least one analyte of interest comprises detecting fluorescence light emitted by the at least one analyte of interest upon excitation of the at least one analyte of interest with excitation light.

27. The method of claim 26, wherein detecting fluorescence light emitted by the at least one analyte of interest comprises optically filtering light between the microfluidic structure and the integrated circuit to reduce intensity of excitation light reaching the integrated circuit.

28. The method of claim 24, wherein optically detecting the at least one analyte of interest comprises optically detecting the at least one analyte of interest in the fluid contained within the microfluidic structure without an intervening waveguide or lens.

29. The method of claim 24, wherein generating said at least one field comprises generating at least one electric or magnetic field having a sufficient strength to interact with the at least one analyte of interest in the microfluidic structure.

30. The method of claim 29, wherein generating said at least one electric or magnetic field comprises:
generating a sufficient voltage or current for generation of the at least one electric or magnetic field;
switching the generated voltage or current from the voltage or current generating component; and
outputting the voltage or current from at least one output to generate the at least one electric or magnetic field.

31. The method of claim 26, further comprising generating the excitation light with the integrated circuit.

32. The method of claim 31, further comprising coordinating the generation of the excitation light with the detection of the fluorescence light emitted by the at least one analyte of interest.

33. The method of claim 24, further comprising communicating with a processor.

34. An integrated circuit operable in association with a microfluidic structure, said integrated circuit comprising:
an optical detector configured to generate an output indicative of light from at least one analyte of interest in a fluid within the microfluidic structure; and
circuitry configured to convert the output of the optical detector to a digital value.

35. The integrated circuit of claim 34, wherein the optical detector is configured to detect fluorescence light emitted by the at least one analyte of interest upon excitation of the at least one analyte of interest by an excitation light source.

36. The integrated circuit of claim 35, wherein the integrated circuit further comprises an optical filter, located between the microfluidic structure and the optical detector, configured to reduce intensity of excitation light from the excitation light source that reaches the optical detector.

37. The integrated circuit of claim 36, wherein the integrated circuit further comprises a conductivity detector configured for contactless capacitive coupling with the microfluidic structure to detect a conductivity of the fluid.

38. The integrated circuit of claim 34, wherein the circuitry configured to convert the output of the optical detector comprises an amplifier configured to amplify the output of the photodetector and an analog-to-digital converter configured to convert the amplified output of the photodetector to a digital value.

39. The integrated circuit of claim 34, wherein the optical detector comprises an avalanche photodiode operable in single photon detection mode.

40. The integrated circuit of claim 34, further comprising a resistive heater configured to heat at least one portion of the microfluidic structure.

41. An apparatus comprising:
a microfluidic structure; and
an integrated circuit according to claim 34 operable in association with the microfluidic structure.
